(19) United States
(12) Patent Application Publication
(10) Pub. No.: US 2016/0086841 A1
(43) Pub. Date: Mar. 24, 2016

(54) METHOD FOR FORMING PATTERN OF SEMICONDUCTOR DEVICE AND SEMICONDUCTOR DEVICE FORMED USING THE SAME

(71) Applicant: SAMSUNG ELECTRONICS CO., LTD., Suwon-si (KR)

(72) Inventors: SEUNGHYUN SONG, Hwaseong-si (KR); Hyeon Kyun Noh, Hwaseong-si (KR); Taeyong Kwon, Suwon-si (KR); Sangsu Kim, Yongin-si (KR); Shigenobu Maeda, Seongnam-si (KR); Krishna Bhuwalka, Suwon-si (KR); Uihui Kwon, Hwaseong-si (KR); Keunho Lee, Seongnam-si (KR); Wonsok Lee, Suwon-si (KR)

(21) Appl. No.: 14/711,394

(22) Filed: May 13, 2015

(30) Foreign Application Priority Data
Sep. 19, 2014 (KR) 10-2014-0125088

(51) Int. Cl. H01L 21/762; H01L 29/10; H01L 21/02; H01L 29/06; H01L 21/308; H01L 29/66

(52) U.S. Cl. CPC H01L 21/76224; H01L 21/3083; H01L 29/66477; H01L 21/02617; H01L 29/0649; H01L 29/1054; H01L 29/0692

(57) ABSTRACT

A method for forming a pattern of a semiconductor device and a semiconductor device formed using the same are provided. The method includes forming a buffer layer on a substrate, forming a channel layer on the buffer layer, forming support patterns penetrating the channel layer, and forming channel fin patterns and a buffer pattern by patterning the channel layer and the buffer layer. The channel layer includes a material of which a lattice constant is different from that of the buffer layer, and each of the channel fin patterns has both sidewalls that are in contact with the support patterns and are opposite to each other.

### CROSS-REFERENCE TO RELATED APPLICATION

This U.S. non-provisional patent application claims under 35 U.S.C. §119 priority to and the benefit of Korean Patent Application No. 10-2014-0125088, filed on Sep. 19, 2014, in the Korean Intellectual Property Office, the entire contents of which are incorporated by reference herein.

### BACKGROUND

The present disclosure relates to methods for forming a pattern of a semiconductor device and semiconductor devices formed using the same, and, more particularly, to methods for forming a pattern of a fin field effect transistor and fin field effect transistors formed using the same.

A semiconductor device may include an integrated circuit including metal-oxide-semiconductor field effect transistors (MOSFETs). As semiconductor devices have become highly integrated, MOSFETs have been increasingly scaled down. Thus, operating characteristics of semiconductor devices have been deteriorating. Various researches are being conducted to overcome limitations caused by the high integration degree of semiconductor devices and to realize semiconductor devices with excellent performance. In particular, techniques capable of increasing mobility of electrons or holes are being developed to help realize high-performance MOSFETs.

Further, fine patterns are necessary to highly integrate semiconductor devices. A size of an individual element should be reduced to integrate a lot of elements in a limited area, so widths of patterns and/or spaces between the patterns should be reduced. As design rules of semiconductor devices have become markedly reduced, it can be difficult to form patterns having a fine pitch by resolution limitations of photolithography processes defining the patterns included in semiconductor devices.

### SUMMARY

Exemplary embodiments of the inventive concepts provide methods for forming a pattern of a semiconductor device capable of improving a mobility characteristic of charges.

Exemplary embodiments of the inventive concepts also provide semiconductor devices capable of improving a mobility characteristic of charges.

In one aspect, a method for forming a pattern of a semiconductor device may include: forming a buffer layer on a substrate; forming a channel layer on the buffer layer; forming support patterns penetrating the channel layer; and forming channel fin patterns and a buffer pattern by patterning the channel layer and the buffer layer. The channel layer may include a material of which a lattice constant is different from that of the buffer layer, and each of the channel fin patterns may have both sidewalls that are in contact with the support patterns and are opposite to each other.

The support patterns may be formed after forming the channel layer. In this case, forming the support patterns may include: forming openings exposing the buffer layer in the channel layer; and filling the openings with an insulating material.

The buffer layer and the channel layer may be sequentially formed by an epitaxial growth process using the substrate as a seed layer.

The support patterns may be formed before forming the channel layer. In this case, forming the support patterns may include: forming a support layer on the buffer layer; and patterning the support layer.

The buffer layer may be formed by an epitaxial growth process using the substrate as a seed layer, and the channel layer may be formed by a selective epitaxial growth process using the buffer layer as a seed layer.

Forming the channel fin patterns may include: forming mask patterns on the channel layer; and etching the channel layer by an etching process using the mask patterns as etch masks to form trenches defining the channel fin patterns. Each of the mask patterns may include both end portions overlapping with the support patterns.

The mask patterns may intersect at least one of the support patterns.

An upper portion of the buffer layer may be partially etched to form the buffer pattern during the etching process for the formation of the trenches. The buffer pattern may include protrusions defined by the trenches, and the channel fin patterns may be formed on top surfaces of the protrusions.

The method may further include forming device isolation patterns in the trenches, the device isolation patterns exposing upper portions of the channel fin patterns. The device isolation patterns may be formed of a different material from the support patterns.

The support patterns may be formed of a material having an etch selectivity with respect to the channel layer and the buffer layer.

The support patterns may be arranged to constitute a plurality of rows and a plurality of columns when viewed from a plan view, and the support patterns of the rows adjacent to each other may be arranged in a zigzag form along one direction.

In another aspect, a method for forming a pattern of a semiconductor device may include: sequentially forming a buffer layer and a channel layer on a substrate; patterning the channel layer and the buffer layer to form first trenches defining preliminary channel fin pattern and a buffer pattern; forming filling insulation patterns filling the first trenches, the filling insulation patterns covering entire portions sidewalls of the preliminary channel fin patterns; and forming a plurality of channel fin patterns from each of the preliminary channel fin patterns. The channel layer may include a material of which a lattice constant is different from that of the buffer layer.

Forming the plurality of channel fin patterns may include: forming mask patterns on the substrate having the filling insulation patterns, the mask patterns partially exposing the preliminary channel fin patterns and the filling insulation patterns; and performing an etching process using the mask patterns as etch masks. The channel fin patterns may be arranged along a first direction and a second direction intersecting the first direction.

The exposed preliminary channel fin patterns and the exposed filling insulation patterns may be etched together by the etching process, thereby forming second trenches extending in the second direction. Each of the preliminary channel fin patterns may be cut by the second trenches so as to be divided into the plurality of channel fin patterns.

The method may further include: forming support patterns filling the second trenches. The support patterns may be formed of a different material from the filling insulation patterns.

The exposed preliminary channel fin patterns among the exposed preliminary channel fin patterns and the exposed filling insulation patterns may be selectively etched by the etching process to form a plurality of holes. Each of the preliminary channel fin pattern may be cut by the holes so as to be divided into the plurality of channel fin patterns. The method may further include forming support patterns filling the holes.

In still another aspect, a semiconductor device may include: a buffer pattern on a substrate; channel fin patterns on the buffer pattern, each of the channel fin patterns including sidewalls opposite to each other in a first direction; support patterns disposed on the buffer pattern, the support patterns being in contact with the sidewalls of the channel fin patterns; device isolation patterns disposed on the buffer pattern, the device isolation patterns exposing upper portions of the channel fin patterns; and a gate electrode extending in a second direction intersecting the first direction to intersect the channel fin patterns. The channel fin patterns may include a material of which a lattice constant is different from that of the buffer pattern, and top surfaces of the device isolation patterns may be lower than top surfaces of the support patterns.

Some of the channel fin patterns may be spaced apart from each other in the first direction, and the support patterns may be disposed between the channel fin patterns spaced apart from each other in the first direction.

The channel fin patterns may include at least a pair of channel fin patterns spaced apart from each other in the second direction, and sidewalls adjacent to each other among sidewalls of the at least the pair of channel fin patterns may be in contact with the same support pattern.

The support patterns may include a different material from the device isolation patterns.

### BRIEF DESCRIPTION OF THE DRAWINGS

FIGS. 1A, 2A, 3A, 4A, 5A, 6A, 7A and 8A are plan views illustrating a method of forming a pattern of a semiconductor device according to exemplary embodiments of the inventive concepts.

FIGS. 1B, 2B, 3B, 4B, 5B, 6B, 7B and 8B are cross-sectional views taken along lines I-I′ and II-II′ of FIGS. 1A, 2A, 3A, 4A, 5A, 6A, 7A and 8A, respectively.

FIGS. 9A, 10A, 11A and 12A are plan views illustrating a modified method of forming a pattern of a semiconductor device according to exemplary embodiments of the inventive concepts.

FIGS. 9B, 10B, 11B and 12B are cross-sectional views taken along lines I-I′ and II-II′ of FIGS. 9A, 10A, 11A and 12A, respectively.

FIGS. 13A, 14A, 15A, 16A and 17A are plan views illustrating a method of forming a pattern of a semiconductor device according to other exemplary embodiments of the inventive concepts.

FIGS. 13B, 14B, 15B and 16B are cross-sectional views taken along lines IV-IV′ and V-V′ of FIGS. 13A, 14A, 15A and 16A, respectively.

FIG. 17B is a cross-sectional view taken along lines IV-IV′, V-V′, and VI-VI′ of FIG. 17A.

FIGS. 18A and 19A are plan views illustrating a modified method of forming a pattern of a semiconductor device according to other exemplary embodiments of the inventive concepts.

FIG. 18B is a cross-sectional view taken along lines IV-IV′ and V-V′ of FIG. 18A.

FIG. 19B is a cross-sectional view taken along lines IV-IV′, V-V′, and VI-VI′ of FIG. 19A.

FIG. 20A is a plan view illustrating a semiconductor device formed using a method for forming a pattern of a semiconductor device according to exemplary embodiments of the inventive concepts.

FIG. 20B is a cross-sectional view taken along lines VII-VII′ and VIII-VIII′ of FIG. 20A.

FIG. 21 is an equivalent circuit diagram of a complementary metal-oxide-semiconductor (CMOS) static random access memory (SRAM) cell including a semiconductor device according to exemplary embodiments of the inventive concepts.

FIG. 22 is a schematic block diagram illustrating an electronic system including a semiconductor device according to exemplary embodiments of the inventive concepts.

FIG. 23 illustrates a mobile phone implemented with an electronic system including a semiconductor device according to exemplary embodiments of the inventive concepts.

### DETAILED DESCRIPTION

The inventive concepts will now be described more fully hereinafter with reference to the accompanying drawings, in which exemplary embodiments of the inventive concepts are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concepts. In the drawings, exemplary embodiments of the inventive concepts are not limited to the specific examples provided herein and may be exaggerated for clarity.

The terminology used herein is for the purpose of describing particular exemplary embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, exemplary embodiments in the detailed description will be described with sectional views as ideal exemplary views of the inventive concepts. Accordingly, shapes of the exemplary views may be modified according to manufacturing techniques and/or allowable errors. Therefore, the exemplary embodiments of the inventive concepts are not limited to the specific shape illustrated in the drawings, but may include other shapes that may be created according to manufacturing processes. Areas exemplified in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in an exemplary embodiment could be termed a second element in other exemplary embodiments without departing from the teachings of the present inventive concepts. Exemplary embodiments of aspects of the present inventive concepts explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of exemplary embodiments.

Devices and methods of forming devices according to various exemplary embodiments described herein may be embodied in microelectronic devices such as integrated circuits, wherein a plurality of devices according to various exemplary embodiments described herein are integrated in the same microelectronic device. Accordingly, the cross-sectional view(s) illustrated herein may be replicated in two different directions, which need not be orthogonal, in the microelectronic device. Thus, a plan view of a microelectronic device that embodies devices according to various exemplary embodiments described herein may include a plurality of the devices in an array and/or in a two-dimensional pattern that is based upon the functionality of the microelectronic device.

The devices according to various exemplary embodiments described herein may be interspersed among other devices depending on the functionality of the microelectronic device. Moreover, microelectronic devices according to various exemplary embodiments described herein may be replicated in a third direction that may be orthogonal to the two different directions, to provide three-dimensional integrated circuits.

Accordingly, the cross-sectional view(s) illustrated herein provide support for a plurality of devices according to various exemplary embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

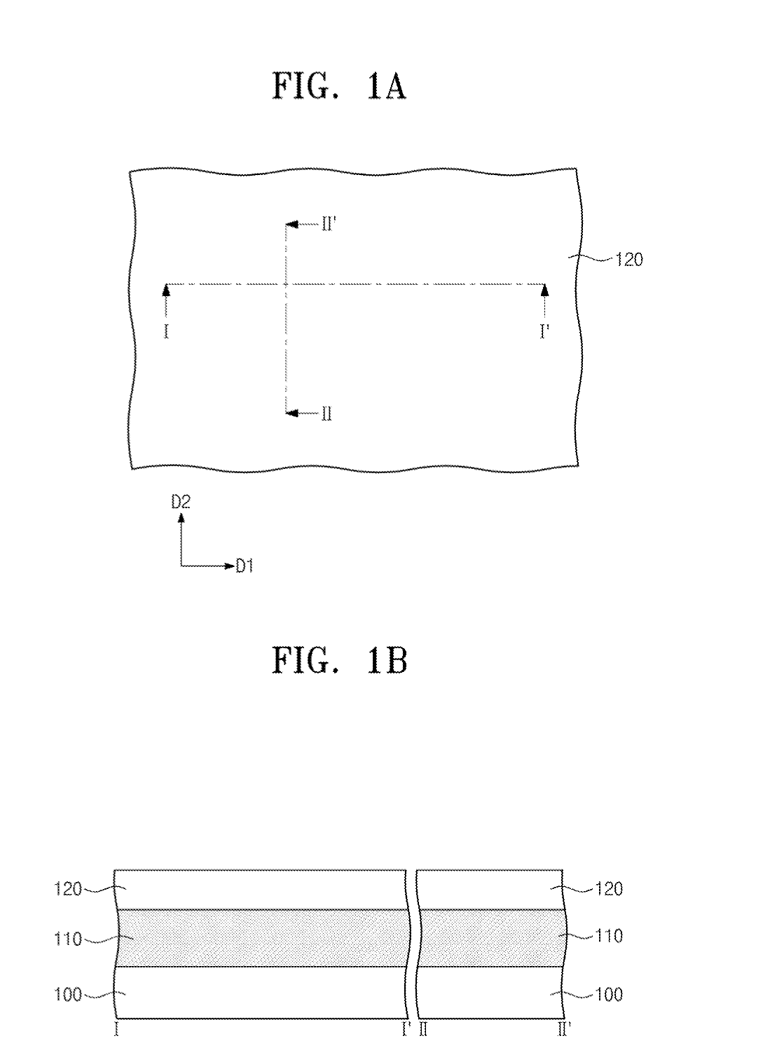

FIGS. 1A, 2A, 3A, 4A, 5A, 6A, 7A and 8A are plan views illustrating a method of forming a pattern of a semiconductor device according to exemplary embodiments of the inventive concepts. FIGS. 1B, 2B, 3B, 4B, 5B, 6B, 7B and 8B are cross-sectional views taken along lines IT and II-IF of FIGS. 1A, 2A, 3A, 4A, 5A, 6A, 7A and 8A, respectively.

Referring to FIGS. 1A and 1B, a buffer layer 110 and a channel layer 120 may be sequentially formed on a substrate 100. The substrate 100 may be a semiconductor substrate including silicon, germanium, or silicon-germanium. Alternatively, the substrate 100 may be a III-V group compound semiconductor substrate.

According to an exemplary embodiment, the buffer layer 110 may be formed of a material of which a lattice constant is different from that of the substrate 100. In addition, the buffer layer 110 and the channel layer 120 may be formed of materials having the same lattice structure but having different lattice constants from each other. In exemplary embodiments, each of the buffer layer 110 and the channel layer 120 may include silicon, germanium, silicon-germanium, or a III-V group compound semiconductor material.

In more detail, if a semiconductor device formed using the exemplary embodiments of the inventive concepts is an N-type metal-oxide-semiconductor (NMOS) field effect transistor, the buffer layer 110 may provide a tensile strain to the channel layer 120. In other words, the buffer layer 110 may have a lattice constant greater than that of the channel layer 120. In exemplary embodiments, the buffer layer 110 may be formed of Si₁₋ₓGeₓ, and the channel layer 120 may be formed of silicon (Si). In other exemplary embodiments, the buffer layer 110 may be formed of Si₁₋ₓGeₓ, and the channel layer 120 may be formed of Si_{1-y}Ge_{y} (where x>y). In still other exemplary embodiments, the buffer layer 110 may be formed of In₁₋ₓGaₓAs, and the channel layer 120 may be formed of In_{1-y}Ga_{y}As (where x<y). Alternatively, if a semiconductor device formed using the exemplary embodiments of the inventive concepts is a P-type MOS (PMOS) field effect transistor, the buffer layer 110 may provide a compressive strain to the channel layer 120. In other words, the buffer layer 110 may have a lattice constant smaller than that of the channel layer 120. In exemplary embodiments, the buffer layer 110 may be formed of Si₁₋ₓGeₓ, and the channel layer 120 may be formed of germanium (Ge). In other exemplary embodiments, the buffer layer 110 may be formed of Si_{1-z}Ge_{z}, and the channel layer 120 may be formed of Si_{1-w}Ge_{w} (where z<w). In still other exemplary embodiments, the buffer layer 110 may be formed of In_{1-z}Ga_{z}As, and the channel layer 120 may be formed of In_{1-w}Ga_{w}As (where z>w). Thus, the strain of the buffer layer 110 may be relaxed but the strain may be applied to the channel layer 120.

The buffer layer 110 and the channel layer 120 may be formed by an epitaxial growth process using the substrate 100 as a seed. In exemplary embodiments, the epitaxial growth process may be a chemical vapor deposition (CVD) process or a molecular beam epitaxy (MBE) process. In an exemplary embodiment, the buffer layer 110 and the channel layer 120 may be sequentially formed in the same chamber.

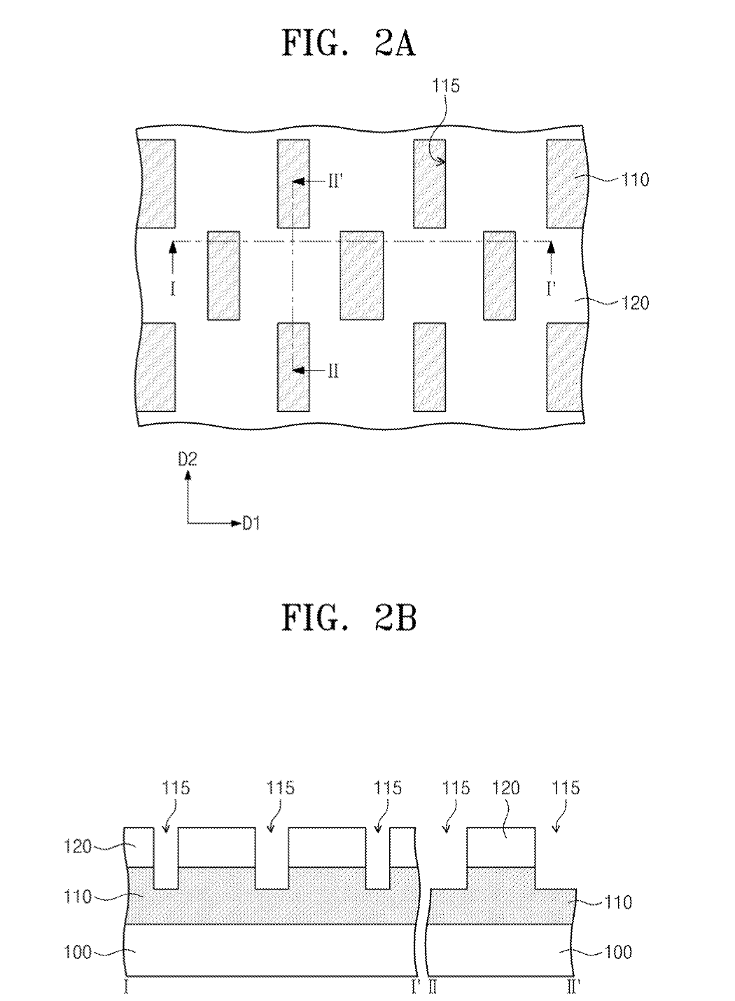

Referring to FIGS. 2A and 2B, openings 115 may be formed in the channel layer 120 to expose the buffer layer 110. According to an exemplary embodiment, a mask pattern (not shown) may be formed on the channel layer 120 and an anisotropic etching process may be performed using the mask pattern as an etch mask to form the openings 115. The anisotropic etching process may be performed until the buffer layer 110 is exposed. A top surface of the buffer layer 110 exposed by each of the openings 115 may be recessed by a predetermined depth through over-etching of the anisotropic etching process. In other words, bottom surfaces of the openings 115 may be lower than a bottom surface of the channel layer 120.

When viewed from a plan view, at least some of the openings 115 may be spaced apart from each other in a first direction D1 to constitute a row. In addition, as illustrated in FIG. 2A, the openings 115 may be two-dimensionally arranged to constitute a plurality of rows and a plurality of columns. Here, the openings 115 of the rows adjacent to each other may be arranged in a zigzag form along the first direction D1. In an exemplary embodiment, each of the openings 115 may have a rectangular shape when viewed from a plan view. However, the inventive concepts are not limited thereto. Unlike FIG. 2A, each of the openings 115 may have a circular shape or a polygonal shape.

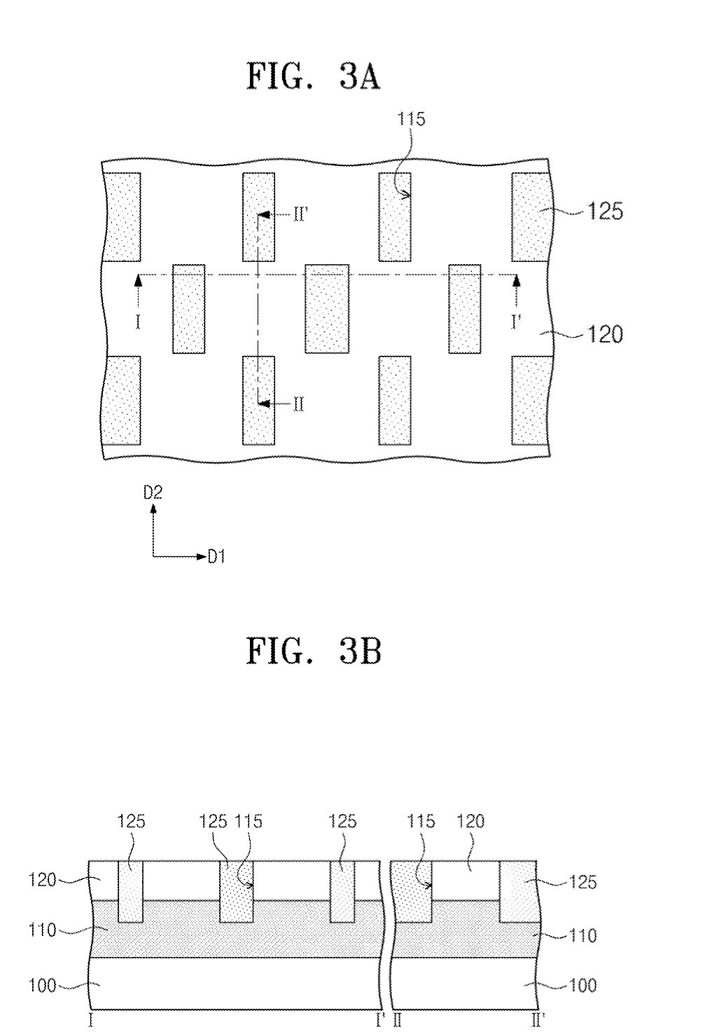

Referring to FIGS. 3A and 3B, support patterns 125 may be formed in the openings 115, respectively. According to an exemplary embodiment, a support layer may be formed on the substrate 100 to fill the openings 115 and a planarization process may be performed on the support layer until the top surface of the channel layer 120 is exposed, thereby forming the support patterns 120. A planar arrangement and planar shapes of the support patterns 125 may correspond to the planar arrangement and the planar shapes of the openings 115, respectively. In addition, bottom surfaces of the support patterns 125 may be lower than the bottom surface of the channel layer 120.

In an exemplary embodiment, the support layer may be formed of a material having an etch selectivity with respect to the channel layer 120 and the buffer layer 110. For example, the support layer may include at least one of an oxide (e.g., silicon oxide), a nitride (e.g., silicon nitride), or an oxynitride (e.g., silicon oxynitride). The planarization process of the support layer may include a chemical mechanical polishing (CMP) process or an etch-back process.

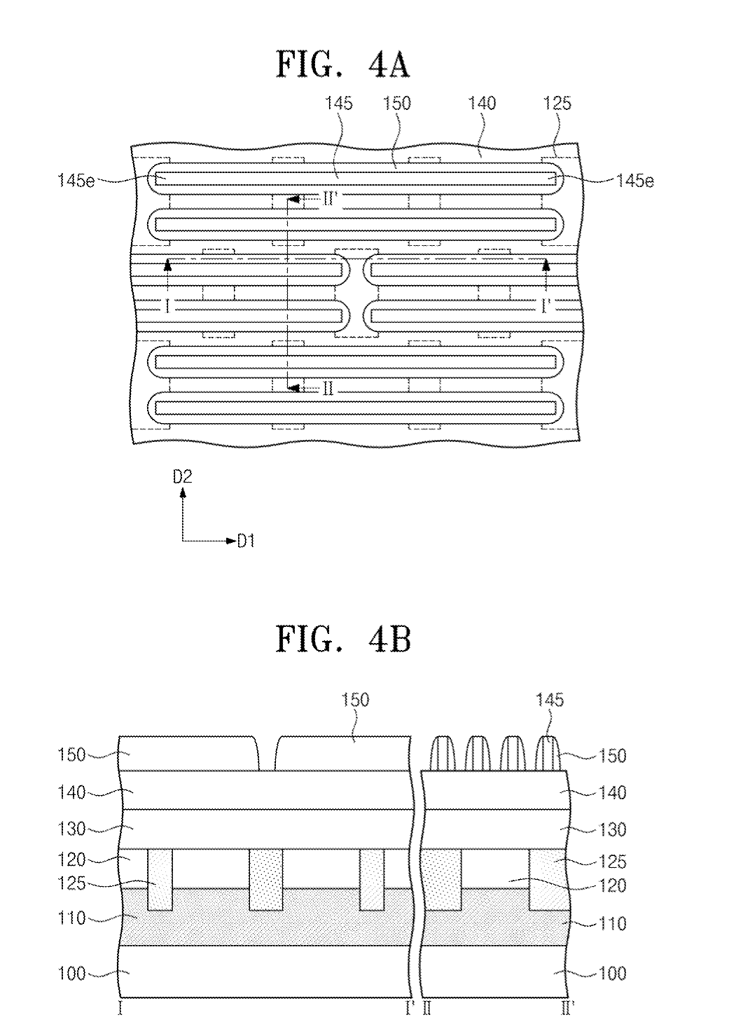

Referring to FIGS. 4A and 4B, a hard mask layer may be formed on the channel layer 120. In an exemplary embodiment, the hard mask layer may include a first mask layer 140 disposed on the channel layer 120 with a second mask layer 130 disposed between the channel layer 120 and the first mask layer 140. The second mask layer 130 may be formed of a material having an etch selectivity with respect to the channel layer 120 and the support patterns 125. For example, the second mask layer 130 may include at least one of silicon oxide, silicon nitride, or silicon oxynitride. The first mask layer 140 may be formed of a material having an etch selectivity with respect to the second mask layer 130. For example, the first mask layer 140 may include poly-silicon. In the present exemplary embodiment, the hard mask layer may have a double-layered structure. However, the inventive concepts are not limited thereto.

Sacrificial patterns 145 may be formed on the first mask layer 140. According to an exemplary embodiment, a sacrificial layer may be formed on the first mask layer 140 and a patterning process may be performed on the sacrificial layer to form the sacrificial patterns 145. The sacrificial layer may include a spin-on-hardmask (SOH) layer or an amorphous carbon layer (ACL). Each of the sacrificial patterns 145 may have a line shape extending in the first direction D1. The sacrificial patterns 145 may be spaced apart from each other in a second direction D2 perpendicular to the first direction D1. Both end portions 145e of each of the sacrificial patterns 145 may overlap with the support patterns 125 when viewed from a plan view. In addition, each of the sacrificial patterns 145 may intersect at least one of the support patterns 125. According to an exemplary embodiment, at least a pair of sacrificial patterns 145 spaced apart from each other in the second direction D2 may extend in parallel along the first direction D1. Here, the at least the pair of sacrificial patterns 145 may intersect one support pattern 125, and the end portions 145e, adjacent to each other, of the end portions 145e thereof may overlap with another support pattern 125.

Next, spacers 150 may be formed to cover sidewalls of the sacrificial patterns 145. In an exemplary embodiment, a spacer layer may be formed on the substrate 100 to conformally cover the sacrificial patterns 145, and a blanket anisotropic etching process may be performed on the spacer layer until the first mask layer 140 is exposed, thereby forming the spacers 150. The spacer layer may include, for example, a silicon oxide layer. The spacer layer may be formed by an atomic layer deposition (ALD) process. Each of the spacers 150 may surround all sidewalls of each of the sacrificial patterns 145. When viewed from a plan view, each of the spacers 150 may have a closed-loop shape surrounding the sacrificial pattern 145. In more detail, the closed-loop shape may have two line portions extending in the first direction D1 and two curved portions connecting the two line portions at the both end portions 145 of the sacrificial pattern 145.

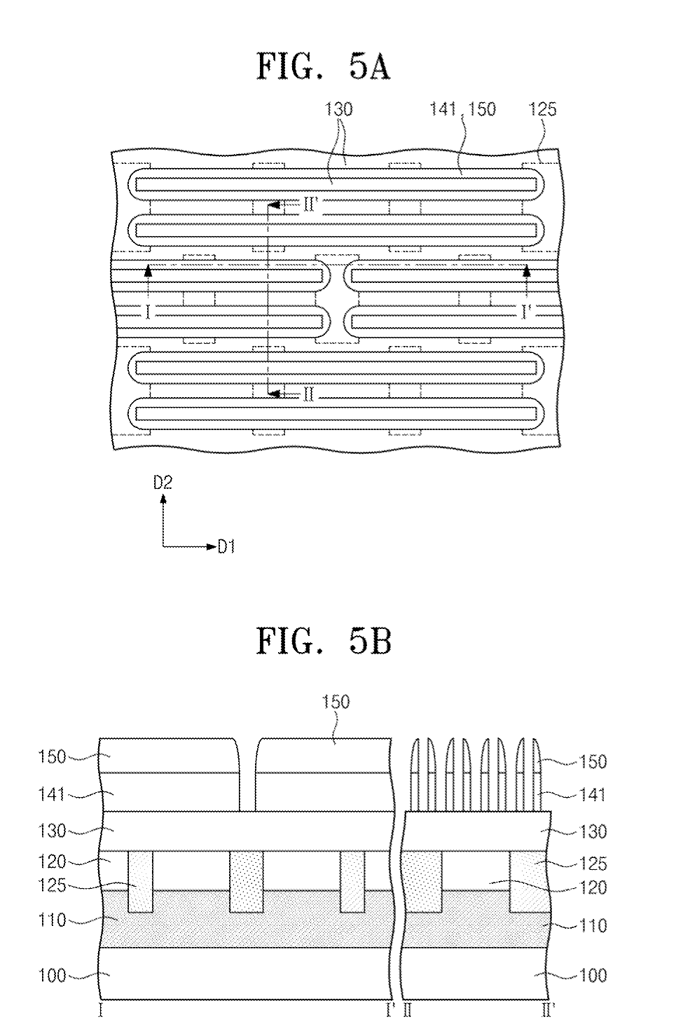

Referring to FIGS. 5A and 5B, the sacrificial patterns 145 may be removed. According to an exemplary embodiment, the sacrificial patterns 145 may be removed by an etching process using an etch recipe having an etch selectivity with respect to the spacers 150 and the first mask layer 140.

Subsequently, the first mask layer 140 may be etched using the spacers 150 as etch masks to form first mask patterns 141. Shapes (e.g., shapes of bottom surfaces) of the spacers 150 may be transferred to the first mask patterns 141. In other words, each of the first mask patterns 141 may have a closed-loop shape which has two line portions extending in the first direction D1 and two end portions connected to ends of the two line portions.

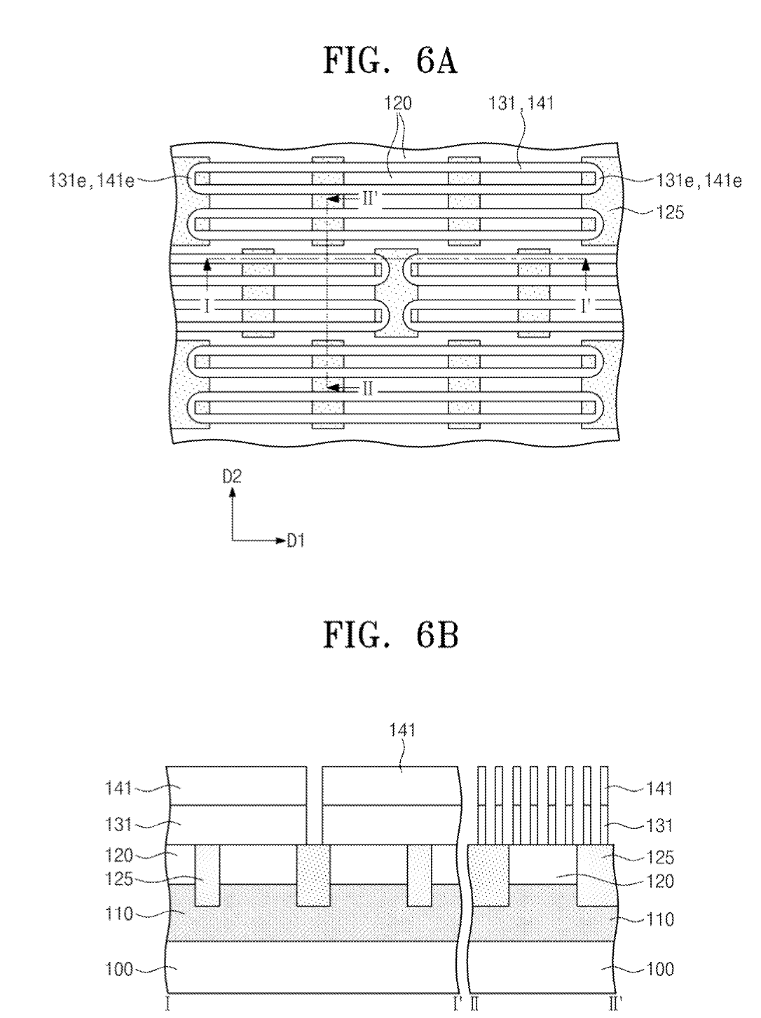

Referring to FIGS. 6A and 6B, the second mask layer 130 may be etched using the first mask patterns 141 as etch masks to form second mask patterns 131. The second mask patterns 131 may have substantially the same shapes as the first mask patterns 141 when viewed from a plan view. In other words, the second mask patterns 131 may have the same closed-loop shapes as the first mask patterns 141 when viewed from a plan view. Both end portions 141e of each of the first mask patterns 141 may overlap with the support patterns 125 in a plan view. Likewise, both end portions 131e of each of the second mask patterns 131 may overlap with the support patterns 125 in a plan view. The spacers 150 may be removed during the etching process for forming the second mask patterns 131. Alternatively, the spacers 150 may be removed before the formation of the second mask patterns 131. The first and second mask patterns 141, 131 may expose the channel layer 120 and the support patterns 125.

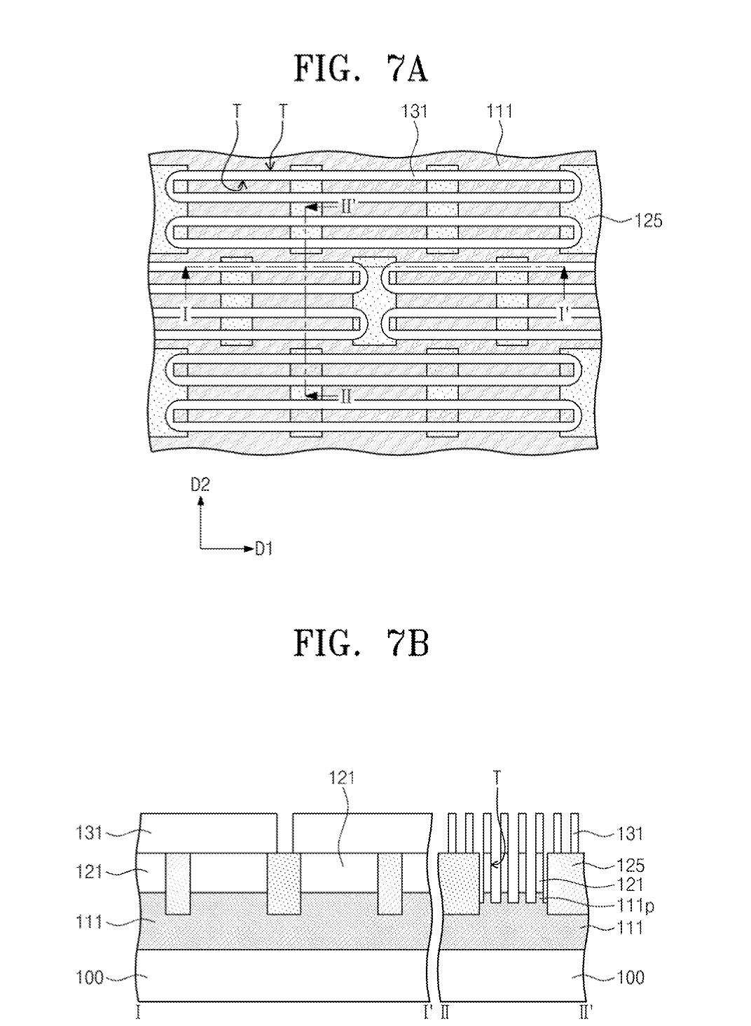

Referring to FIGS. 7A and 7B, the channel layer 120 may be etched using the first and second mask patterns 141, 131 as etch masks to form trenches T defining channel fin patterns 121. In addition, an upper portion of the buffer layer 110 may be etched to form a buffer pattern 111 when the trenches T are formed. The buffer pattern 111 may include protrusions 111p defined by the trenches T, and the channel fin patterns 121 may be formed on top surfaces of the protrusions 111p, respectively. Since the support patterns 125 are formed of the material having an etch selectivity with respect to the channel layer 120 and the buffer layer 110, an etched amount of the support patterns 125 may be minimized during the formation of the trenches T.

Each of the channel fin patterns 121 may have both sidewalls that are self-aligned by the support patterns 125 adjacent to each other in the first direction D1. In other words, each of the channel fin patterns 121 may have the both sidewalls that are opposite to each other in a longitudinal direction (i.e., the first direction D1) and are in contact with the support patterns 125. The channel fin patterns 121 may be arranged in the first direction D1 and the second direction D2, and the support pattern 125 may be disposed between the channel fin patterns 121 spaced apart from each other in the first direction D1. According to an exemplary embodiment, at least a pair of the channel fin patterns 121 may be spaced apart from each other in the second direction D2 and may extend in parallel along the first direction D1. Here, sidewalls, adjacent to each other, of sidewalls of the at least the pair of channel fin patterns 121 may be in contact with the same support pattern 125.

Further, during the formation of the trenches T, the first mask patterns 141 may be removed but the second mask patterns 131 may remain.

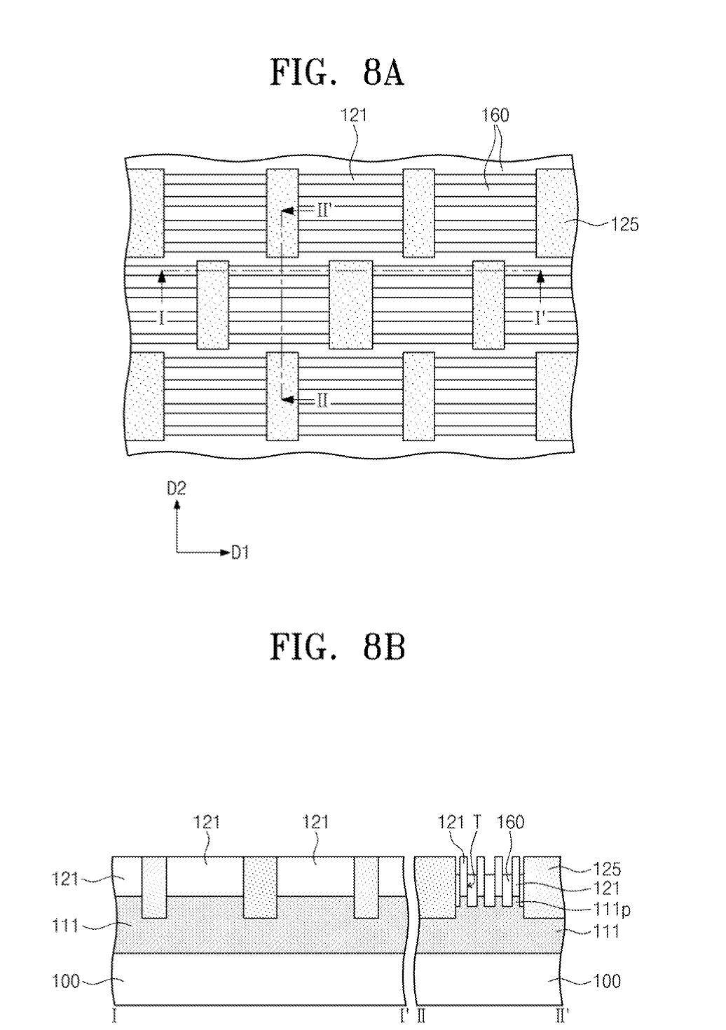

Referring to FIGS. 8A and 8B, the second mask patterns 131 may be removed. The removal of second mask patterns 131 may be performed by, for example, a wet etching process.

Thereafter, device isolation patterns 160 may be formed in the trenches T. In more detail, a device isolation layer may be formed on the substrate 100 to fill the trenches T. Next, the device isolation layer may be planarized until the channel fin patterns 121 and the support patterns 125 are exposed, and the planarized device isolation layer may be recessed. As a result, the device isolation patterns 160 may be formed to expose upper portions of the channel fin patterns 121, for example, upper portions of sidewalls opposite to each other in the second direction D2 of the channel fin patterns 121. In addition, the device isolation patterns 160 may also expose upper portions of the support patterns 125. In other words, top surfaces of the device isolation patterns 160 may be lower than the top surfaces of the support patterns 125. The device isolation layer may be formed of an insulating material having an excellent gap-fill characteristic. In exemplary embodiments, the device isolation layer may include at least one of O₃-tetra ethyl ortho silicate (O₃-TEOS), undoped silicate glass (USG), phosphosilicate glass (PSG), borosilicate glass (BSG), borophosphosilicate glass (BPSG), a high-density plasma (HDP) oxide, undoped silicate glass (USG), fluoride silicate glass (FSG), spin-on-glass (SOG), or Tonen SilaZene (TOSZ). In other exemplary embodiments, the device isolation layer may include at least one of silicon nitride or silicon oxynitride. In an exemplary embodiment, the device isolation layer may be formed of a different material from the support patterns 125. The planarization process performed on the device isolation layer may include a CMP process or an etch-back process.

According to the exemplary embodiment described above, the strain may be applied to the channel layer 120 by the buffer layer 110, so the strain may also be applied to the channel fin patterns 121 formed by patterning the channel layer 120. The strain applied to the channel fin patterns 121 may increase a charge mobility of field effect transistors formed using the channel fin patterns 121. In other words, the strain in the longitudinal direction (i.e., a movement direction of charges) of the channel fin pattern 121 may correspond to an important factor for increasing the charge mobility. However, if both ends (e.g., both ends in the longitudinal direction) of the channel fin pattern 121 are exposed during the formation of the channel fin pattern 121, the strain applied to the channel fin pattern 121 may be degraded or reduced. According to exemplary embodiments of the inventive concepts, the support patterns 125, which may be spaced apart from each other in the longitudinal direction of the channel fin pattern 121, may be formed in the channel layer 120. Thereafter, the channel layer 120 may be patterned to form the channel fin patterns 121 of which each has the both sidewalls self-aligned by the support patterns 125. In other words, the both ends of each of the channel fin patterns 121, which are opposite to the longitudinal direction of the channel fin pattern 121, may be in contact with the support patterns 125. As a result, the both ends of each of the channel fin patterns 121 may not be exposed during the formation of the channel fin patterns 121. This means that it is possible to prevent the degradation of the strain applied to the channel fin patterns 121 (i.e., the degradation of the strain in the longitudinal direction corresponding to the movement direction of the charges).

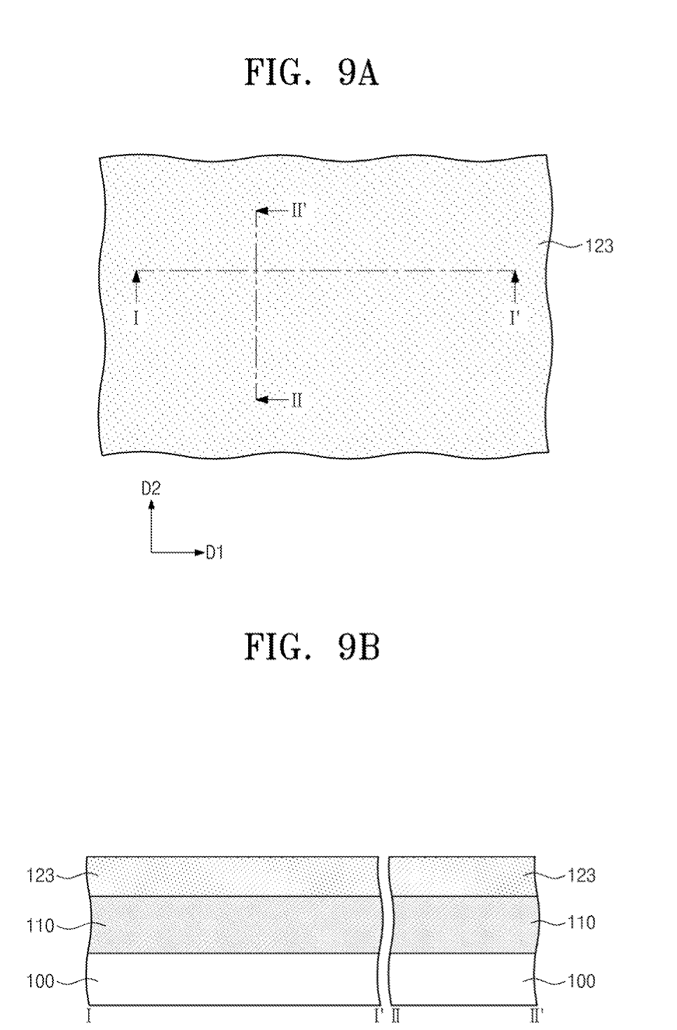

FIGS. 9A, 10A, 11A and 12A are plan views illustrating a modified method of forming a pattern of a semiconductor device according to exemplary embodiments of the inventive concepts. FIGS. 9B, 10B, 11B and 12B are cross-sectional views taken along lines I-I′ and II-II′ of FIGS. 9A, 10A, 11A and 12A, respectively. A method for forming a pattern of a semiconductor device according to the present modified embodiment may be the substantially same as the method for forming the pattern according to the above embodiment except a method for forming support patterns. In the present modified embodiment, the descriptions to the same elements as described in the above embodiment will be omitted or mentioned briefly for the purpose of ease and convenience in explanation.

Referring to FIGS. 9A and 9B, a buffer layer 110 and a support layer 123 may be sequentially formed on a substrate 100. The buffer layer 110 may be formed of a material of which a lattice constant is different from that of the substrate 100, as described with reference to FIGS. 1A and 1B. For example, the buffer layer 110 may include silicon, germanium, silicon-germanium, or a III-V group compound semiconductor material and may have the lattice constant different from that of the substrate 100. The buffer layer 110 may be formed by an epitaxial growth process using the substrate 100 as a seed layer.

The support layer 123 may be formed of the same material as the support layer described with reference to FIGS. 3A and 3B. In other words, the support layer 123 may include at least one of an oxide (e.g., silicon oxide), a nitride (e.g., silicon nitride), or an oxynitride (e.g., silicon oxynitride). The support layer 123 may be formed of a CVD process.

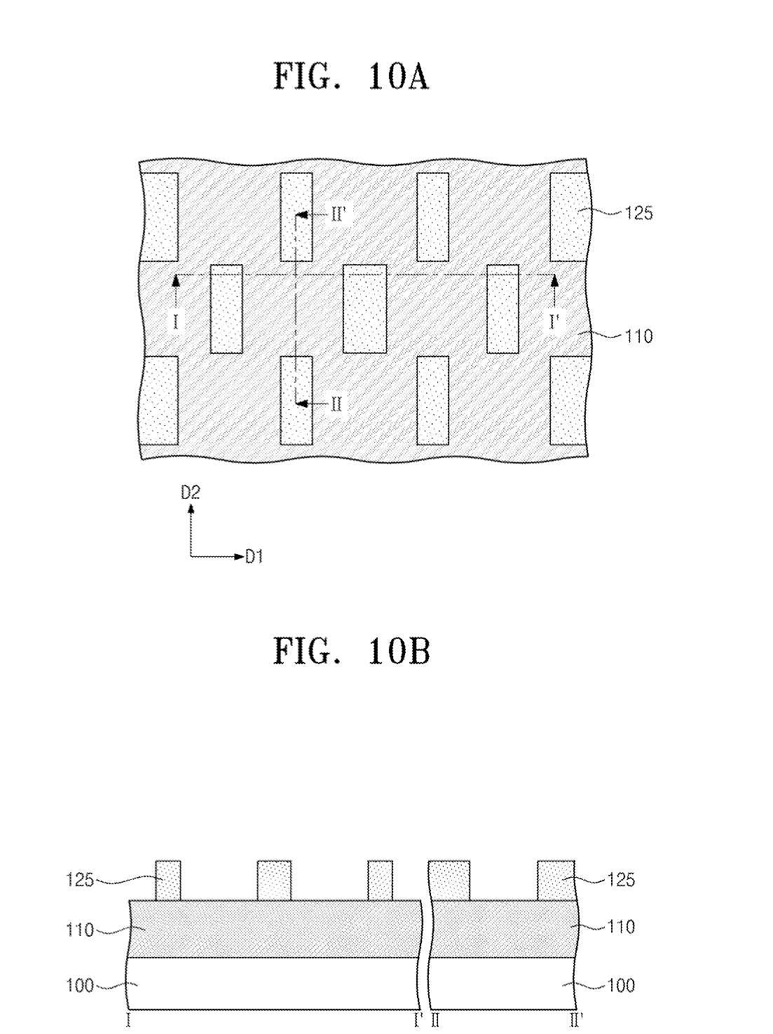

Referring to FIGS. 10A and 10B, a patterning process may be performed on the support layer 123 to form support patterns 125. In more detail, mask patterns (not shown) may be formed on the support layer 123, and the support layer 123 may be etched using the mask patterns as etch masks to form the support patterns 125. The support patterns 125 may have the same planar arrangement and the same planar shapes as the support patterns 125 described with reference to FIGS. 3A and 3B.

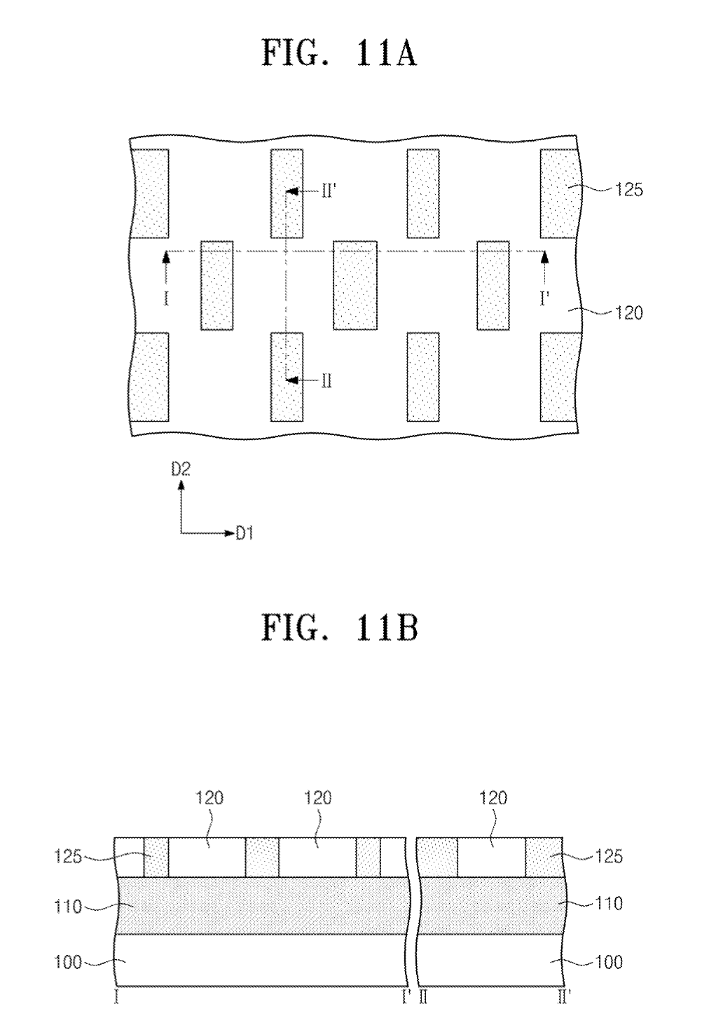

Referring to FIGS. 11A and 11B, a channel layer 120 may be formed on the buffer layer 110 on which the support patterns 125 are formed. According to an exemplary embodiment, the channel layer 120 may be formed by a selective epitaxial growth (SEG) process using the buffer layer 110 as a seed layer. As described with reference to FIGS. 1A and 1B, the channel layer 120 may include silicon, germanium, silicon-germanium, or a III-V group compound semiconductor material and may have a lattice constant different from that of the buffer layer 110. According to an exemplary embodiment, the channel layer 120 may protrude from top surfaces of the support patterns 125 by over-growth when the channel layer 120 is formed using the SEG process. In this case, a planarization process (e.g., a CMP process) may be performed to planarize a top surface of the channel layer 120. As a result, the support patterns 125 may penetrate the channel layer 120. In addition, a bottom surface of the channel layer 120 may be disposed at the substantially same height as bottom surfaces of the support patterns 125.

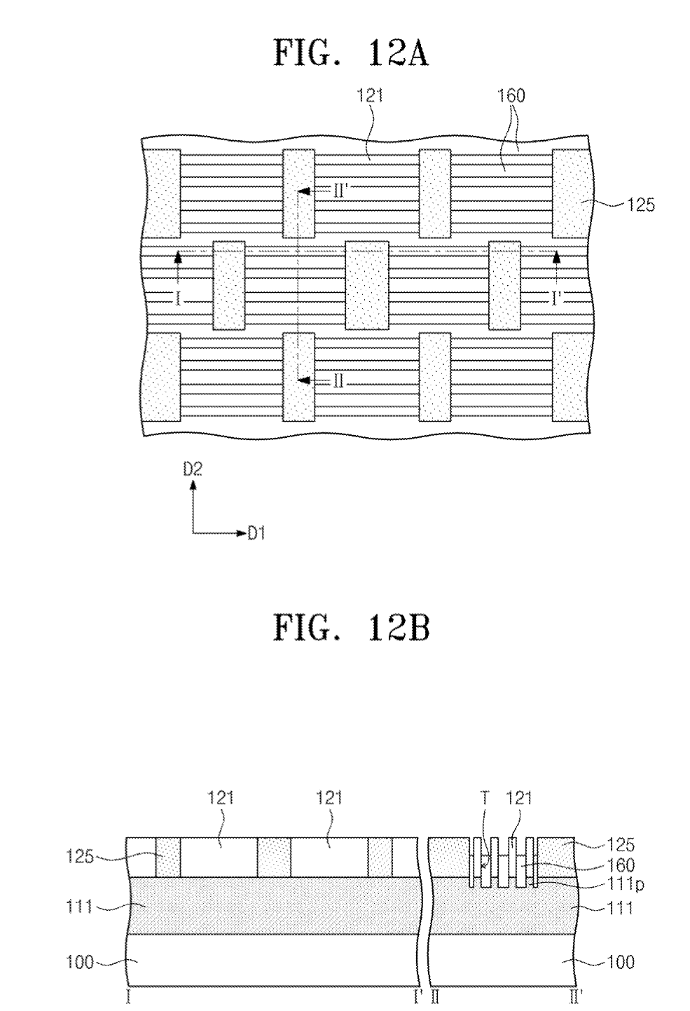

Referring to FIGS. 12A and 12B, a patterning process may be performed on the channel layer 120 and the buffer layer 110 to form trenches T defining channel fin patterns 121 and a buffer pattern 111. In more detail, the patterning process of the channel layer 120 and the buffer layer 110 may include a process of forming mask patterns (not shown) on the channel layer 120 and an etching process using the mask patterns as etch masks. The process of forming the mask patterns and the etching process using the mask patterns may be the substantially same as the process of forming the first and second mask patterns 141, 131 and the etching process using the first and second mask patterns 141, 131 described with reference to FIGS. 4A to 7A and 4B to 7B. Next, device isolation patterns 160 may be formed to fill the trenches T and to expose upper portions of the channel fin patterns 121. The method of forming the device isolation patterns 160 may be the substantially same as described with reference to FIGS. 8A and 8B.

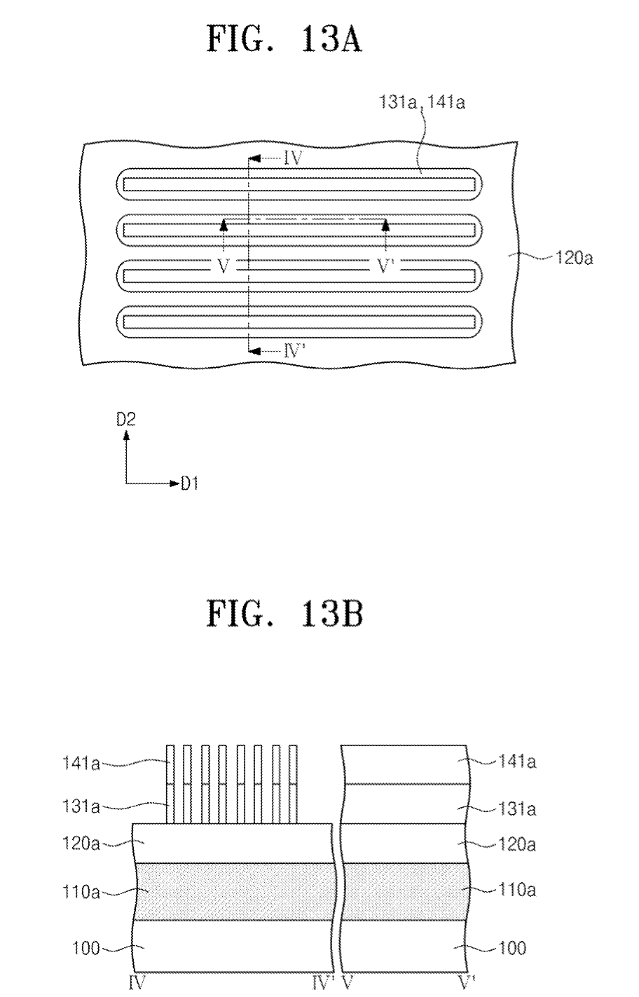

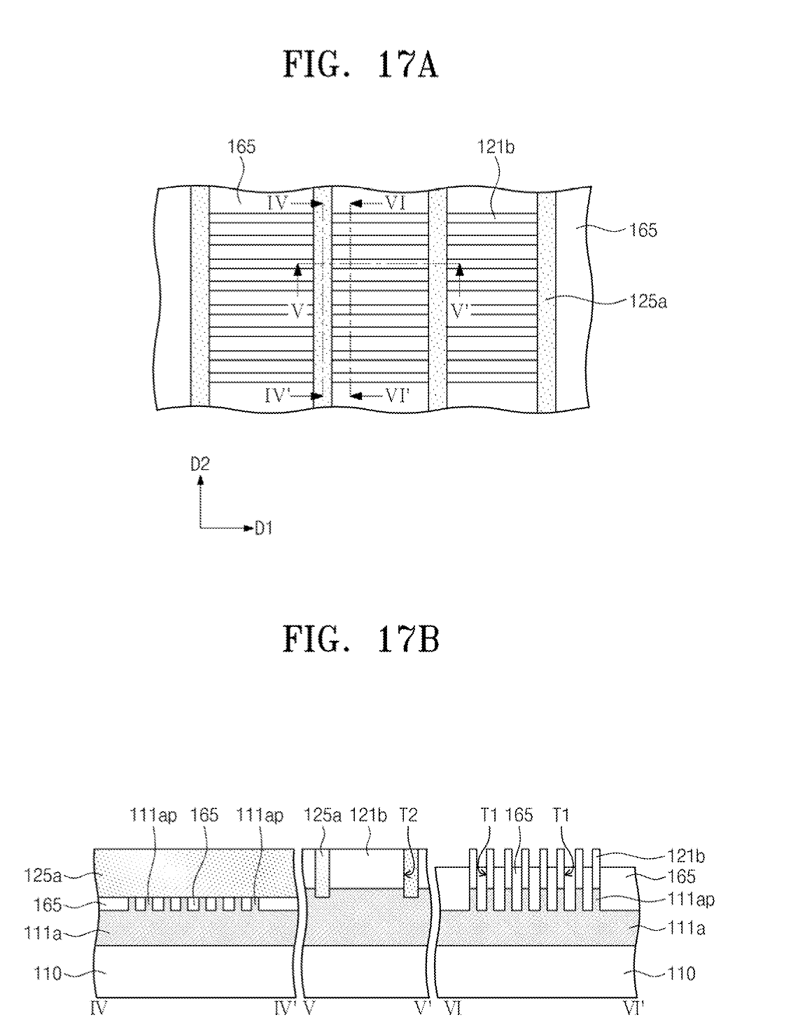

FIGS. 13A, 14A, 15A, 16A and 17A are plan views illustrating a method of forming a pattern of a semiconductor device according to other exemplary embodiments of the inventive concepts. FIGS. 13B, 14B, 15B and 16B are cross-sectional views taken along lines IV-IV′ and V-V′ of FIGS. 13A, 14A, 15A and 16A, respectively. FIG. 17B is a cross-sectional view taken along lines IV-IV′, V-V′, and VI-VI′ of FIG. 17A.

Referring to FIGS. 13A and 13B, a buffer layer 110a and a channel layer 120a may be sequentially formed on a substrate 100. The substrate 100 may be a semiconductor substrate including silicon, germanium, or silicon-germanium. Alternatively, the substrate 100 may be a III-V group compound semiconductor substrate.

According to an exemplary embodiment, the buffer layer 110a and the channel layer 110a may be formed of the same materials as the buffer layer 110 and the channel layer 120 described with reference to FIGS. 1A and 1B. In addition, the buffer and channel layers 110a, 120a may be formed by the same methods as the buffer and channel layers 110, 120 of FIGS. 1A and 1B. In other words, the buffer layer 110a and the channel layer 120a may have the same lattice structure but may have different lattice constants from each other. Thus, a strain of the buffer layer 110a may be relaxed but a strain may be applied to the channel layer 120a. In exemplary embodiments, the lattice constant of the buffer layer 110a may be greater than that of the channel layer 120a, so a tensile strain may be applied to the channel layer 120a. In other exemplary embodiments, the lattice constant of the buffer layer 110a may be smaller than that of the channel layer 120a, so a compressive strain may be applied to the channel layer 120a.

First mask patterns 141a may be formed on the channel layer 120a, and a second mask pattern 131a may be formed between the channel layer 120a and each of the first mask patterns 141a. Each of the first mask patterns 141a may have a closed-loop shape which has two lines extending in parallel along a first direction D1 and end portions connecting ends of the two lines to each other. The first mask patterns 141a may be spaced apart from each other in a second direction D2. Second mask patterns 131a may have the same arrangement and the same shapes as the first mask patterns 141a. The first and second mask patterns 141a, 131a may be formed of the same materials as described with reference to FIGS. 4A to 6A and 4B to 6B. In addition, the first and second mask patterns 141a, 131a may be formed by the same methods as described with reference to FIGS. 4A to 6A and 4B to 6B.

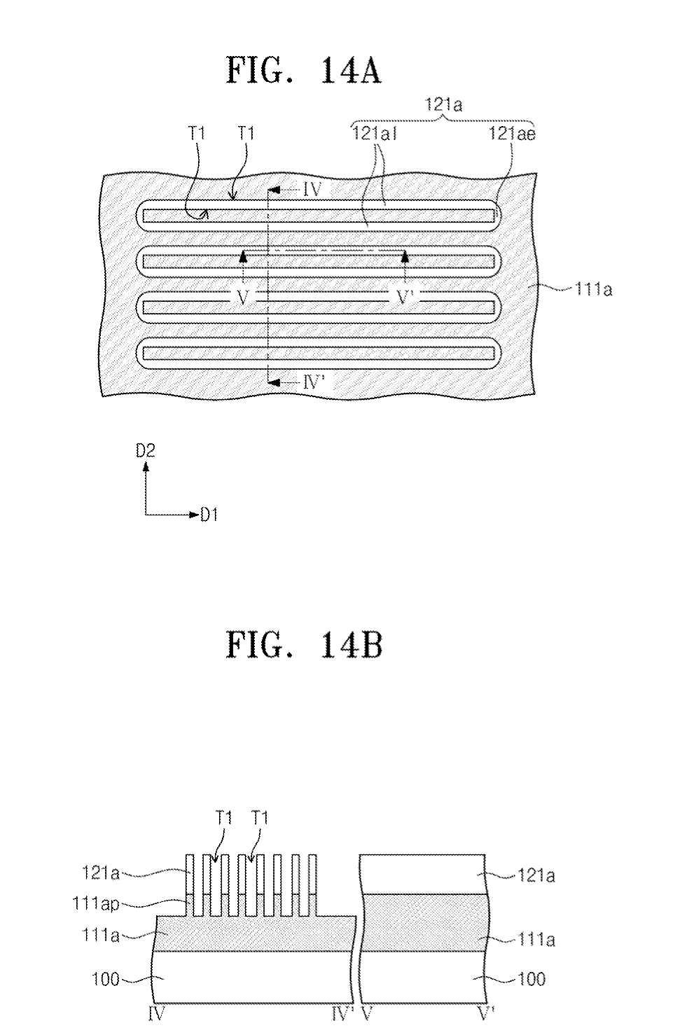

Referring to FIGS. 14A and 14B, the channel layer 120a may be etched using the first and second mask patterns 141a, 131a as etch masks to form first trenches T1 defining preliminary channel fin patterns 121a. In addition, an upper portion of the buffer layer 110a may be etched to form a buffer pattern 111a when the first trenches T1 are formed. The buffer pattern 111a may include protrusions 111ap defined by the first trenches T1, and the preliminary channel fin patterns 121a may be formed on top surfaces of the protrusions 111ap, respectively. When viewed from a plan view, the preliminary channel fin patterns 121a may have the substantially same closed-loop shapes as the first and second mask patterns 141a, 131a. In more detail, each of the preliminary channel fin patterns 121a may include a pair of line patterns 121al extending in parallel along the first direction D1 and both end portions 121ae connecting the pair of line patterns 121al. The pair of line patterns 121al may be spaced apart from each other in the second direction. The both end portions 121ae of the preliminary channel fin patterns 121a may have rounded shapes when viewed from a plan view.

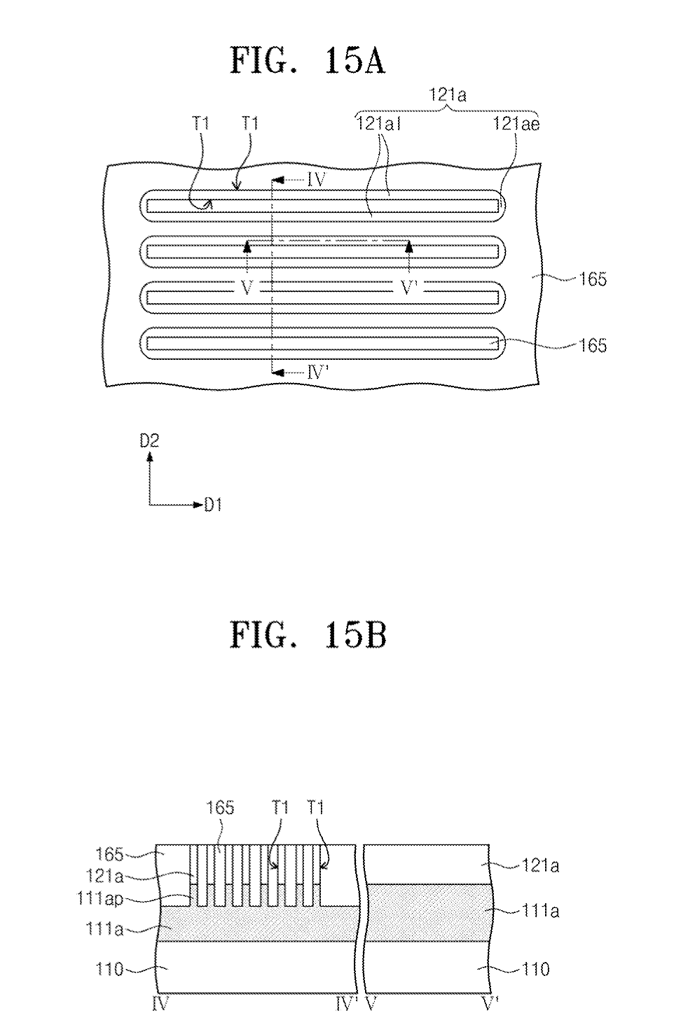

Referring to FIGS. 15A and 15B, filling insulation patterns 165 may be formed in the first trenches T1, respectively. According to an exemplary embodiment, a filling insulation layer may be formed on the substrate 100 to fill the first trenches T1. A planarization process may be performed on the filling insulation layer until top surfaces of the preliminary channel fin patterns 121a are exposed, thereby forming the filling insulation patterns 165. As a result, the filling insulation patterns 165 may cover entire portions of sidewalls of the preliminary channel fin patterns 121a. In an exemplary embodiment, the filling insulation layer may be formed of a material having an etch selectivity with respect to the preliminary channel fin patterns 121a and the buffer pattern 111a. In addition, the filling insulation layer may be formed of a material having an excellent gap-fill characteristic. In exemplary embodiments, the filling insulation layer may include at least one of O₃-tetra ethyl ortho silicate (O₃-TEOS), undoped silicate glass (USG), phosphosilicate glass (PSG), borosilicate glass (BSG), borophosphosilicate glass (BPSG), a high-density plasma (HDP) oxide, undoped silicate glass (USG), fluoride silicate glass (FSG), spin-on-glass (SOG), or Tonen SilaZene (TOSZ). In other exemplary embodiments, the filling insulation layer may include at least one of silicon nitride or silicon oxynitride. The filling insulation layer may be deposited using a deposition technique with excellent step coverage. The planarization process performed on the filling insulation layer may include a CMP process or an etch-back process. In exemplary embodiments, the filling insulation patterns 165 may correspond to device isolation patterns.

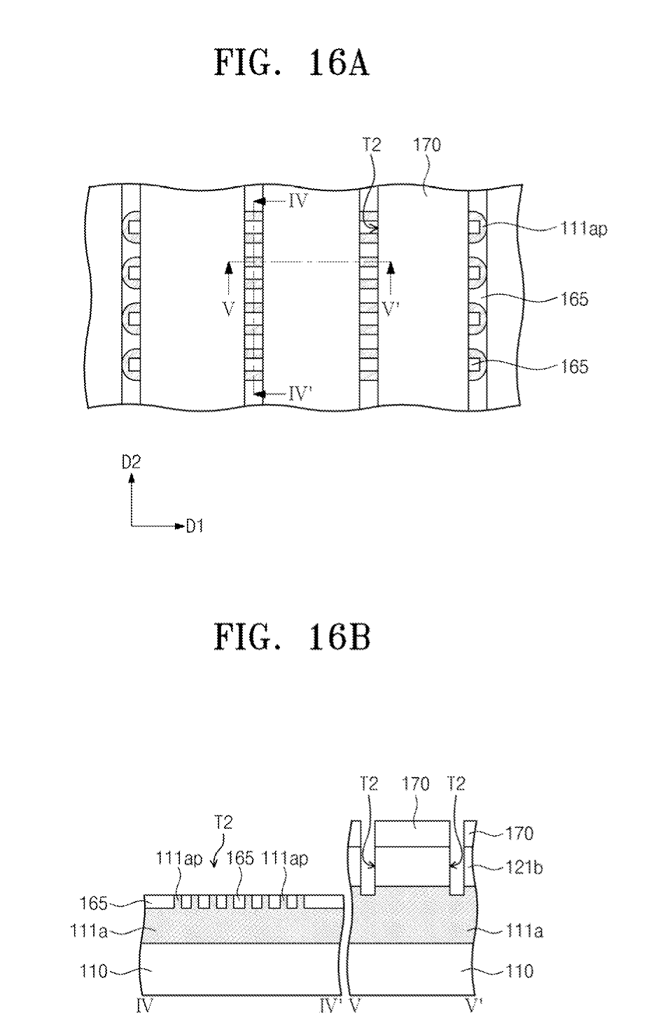

Referring to FIGS. 16A and 16B, third mask patterns 170 may be formed on the resultant structure of FIGS. 15A and 15B, and an etching process may be performed using the third mask patterns 170. The both end portions 121ae of each of the preliminary channel fin patterns 121a and portions of the pair of line patterns 121al between the both end portions 121ae, which are exposed by the third mask patterns 170, may be removed by the etching process to expose the protrusions 111ap of the buffer pattern 111a. In addition, the filling insulation patterns 165 exposed by the third mask patterns 170 may also be etched when the preliminary channel fin patterns 121a are etched. As a result, second trenches T2 may be formed to cut each of the preliminary channel fin patterns 121a into a plurality of channel fin patterns 121b. The second trenches T2 may extend in the second direction D2 intersecting the first direction D1. Thus, the channel fin patterns 121b may be formed to be arranged along the first direction D1 and the second direction D2. On the other hand, the protrusions 111ap of the buffer pattern 111a exposed by the third mask patterns 170 may be partially etched during the etching process for the formation of the second trenches T2. According to an exemplary embodiment, the third mask patterns 170 may include a photoresist material, and at least portions of the third mask patterns 170 may remain after the formation of the second trenches T2.

Referring to FIGS. 17A and 17B, the third mask patterns 170 may be removed, and support patterns 125a may be then formed in the second trenches T2. The removal of the third mask patterns 170 may be performed by, for example, an aching process and/or a strip process.

According to an exemplary embodiment, a support layer may be formed on the substrate 100 to fill the second trenches T2. A planarization process may be performed on the support layer until top surfaces of the channel fin patterns 121b are exposed, thereby forming the support patterns 125a. The support patterns 125a may extend in the second direction D2 and may be in contact with sidewalls of the channel fin patterns 121b. In other words, both sidewalls of the channel fin pattern 121b opposite to each other in a longitudinal direction (i.e., the first direction D1) of the channel fin pattern 121b may be in contact with the support patterns 125a. In an exemplary embodiment, the support patterns 125a may be formed of a material having an etch selectivity with respect to the filling insulation patterns 165. For example, the support patterns 125a may include silicon oxide, silicon nitride, or silicon oxynitride.

Subsequently, upper portions of the filling insulation patterns 165 may be recessed to expose upper portions of the channel fin patterns 121b. In other words, upper portions of both sidewalls of the channel fin pattern 121b opposite to each other in the second direction D2 may be exposed. According to an exemplary embodiment, the filling insulation patterns 165 may be recessed by an etching process using an etch recipe having an etch selectivity with respect to the channel fin patterns 121b and the support patterns 125a.

According to the present exemplary embodiment, before the formation of the second trenches T2 dividing the preliminary channel fin patterns 121a into the channel fin patterns 121b, the filling insulation patterns 165 may be formed to fill the first trenches T1 defining the preliminary channel fin patterns 121a. Thus, even though both ends of the channel fin patterns 121b are exposed by the second trenches T2 during the formation of the channel fin patterns 121b, degradation of the strain applied to the channel fin patterns 121b may be minimized or prevented by the filling insulation patterns 165 which are in contact with the channel fin patterns 121b. In addition, since the support patterns 125a are formed to fill the second trenches T2, it is possible to prevent the strain applied to the channel fin patterns 121b (i.e., the strain in the longitudinal direction corresponding to a movement direction of charges) from being degraded in subsequent processes.

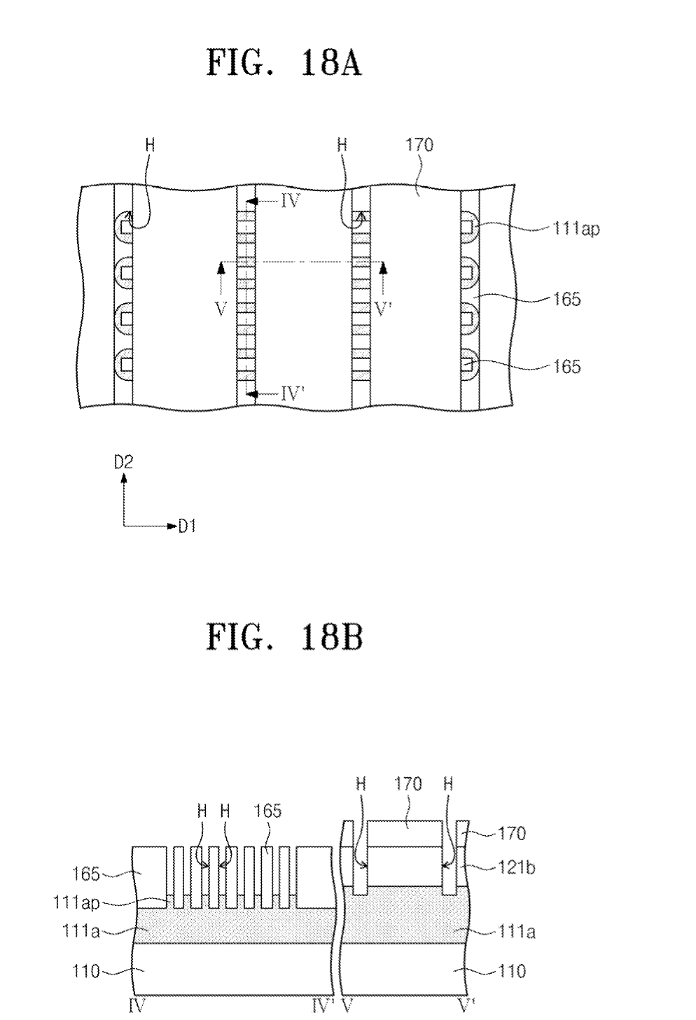

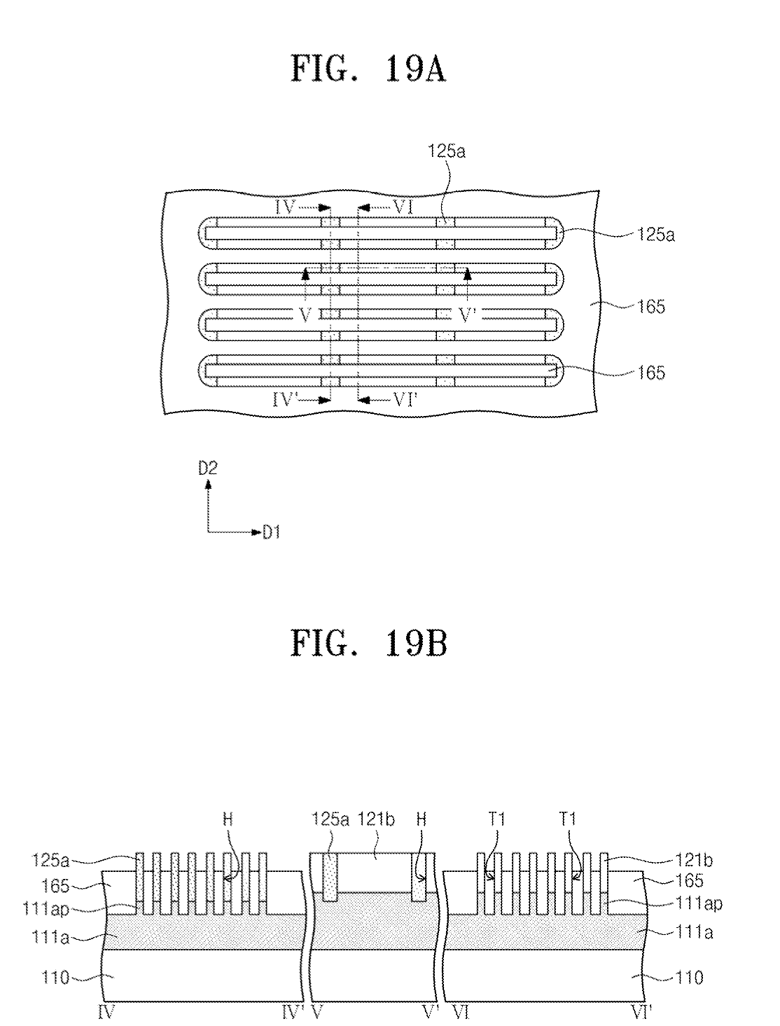

FIGS. 18A and 19A are plan views illustrating a modified method of forming a pattern of a semiconductor device according to other exemplary embodiments of the inventive concepts. FIG. 18B is a cross-sectional view taken along lines IV-IV′ and V-V′ of FIG. 18A, and FIG. 19B is a cross-sectional view taken along lines IV-IV′, V-V′, and VI-VI′ of FIG. 19A. In the present modified embodiment, the descriptions to the same elements as in the exemplary embodiment of FIGS. 9A to 12A and 9B to 12B will be omitted or mentioned briefly for the purpose of ease and convenience in explanation.

Referring to FIGS. 18A and 18B, the third mask patterns 170 may be formed on the resultant structure of FIGS. 15A and 15B. Thereafter, the preliminary channel fin patterns 121a exposed by the third mask patterns 170 may be selectively removed but the filling insulation patterns 165 exposed by the third mask patterns 170 may remain. In other words, the both end portions 121ae of each of the preliminary channel fin patterns 121a and portions of the pair of line patterns 121al between the both end portions 121ae, which are exposed by the third mask patterns 170, may be removed to expose the protrusions 111ap of the buffer pattern 111a. In an exemplary embodiment, the preliminary channel fin patterns 121a may be selectively removed by an etching process using an etch recipe having an etch selectivity with respect to the filling insulation patterns 165. As a result, holes H may be formed to cut each of the preliminary channel fin patterns 121a into a plurality of channel fin patterns 121b. Some sidewalls of the holes H may be defined by the filling insulation patterns 165. Thus, the channel fin patterns 121b may be formed to be arranged in the first direction D1 and the second direction D2. The protrusions 111ap of the buffer pattern 111a may be partially etched during the etching process for the formation of the holes H. According to an exemplary embodiment, the third mask patterns 170 may include a photoresist material and may remain after the formation of the holes H.

Referring to FIGS. 19A and 19B, the third mask patterns 170 may be removed. The removal of the third mask patterns 170 may be performed by, for example, an ashing process and/or a strip process. Subsequently, support patterns 125a may be formed in the holes H. According to an exemplary embodiment, a support layer may be formed on the substrate 100 to fill the holes H. A planarization process may be performed on the support layer until top surfaces of the channel fin patterns 121b are exposed, thereby forming the support patterns 125a. In an exemplary embodiment, the support patterns 125a may be formed of a material having an etch selectivity with respect to the filling insulation patterns 165. For example, the support patterns 125a may include silicon oxide, silicon nitride, or silicon oxynitride. As a result, both sidewalls of each of the channel fin patterns 121b, which are opposite to in the longitudinal direction (i.e., the first direction D1) of the channel fin pattern 121b, may be in contact with the support patterns 125a.

Next, upper portions of the filling insulation patterns 165 may be recessed to expose upper portions of the channel fin patterns 121b. In other words, upper portions of both sidewalls of the channel fin pattern 121b opposite to each other in the second direction D2 may be exposed. Recessing the filling insulation patterns 165 may be the same as described with reference to FIGS. 17A and 17B.

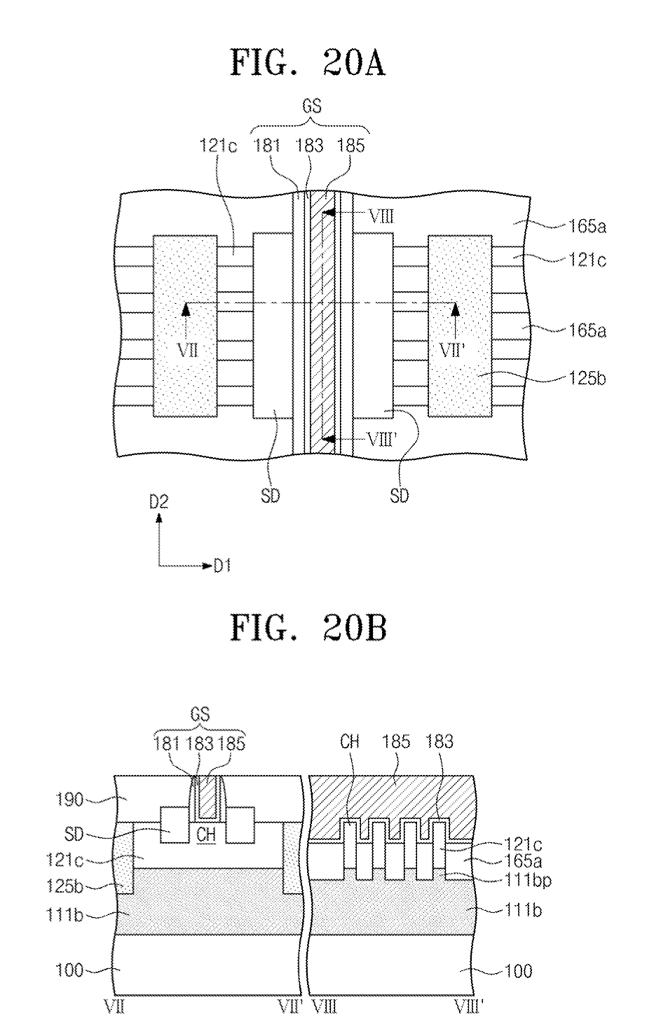

A semiconductor device formed by the method for forming the pattern according to exemplary embodiments of the inventive concepts will be described with reference to FIGS. 20A and 20B.

FIG. 20A is a plan view illustrating a semiconductor device formed using a method for forming a pattern of a semiconductor device according to exemplary embodiments of the inventive concepts. FIG. 20B is a cross-sectional view taken along lines VII-VII′ and VIII-VIII′ of FIG. 20A.

Referring to FIGS. 20A and 20B, a buffer pattern 111b may be disposed on a substrate 100, and channel fin patterns 121c may be disposed on the buffer pattern 111b. The substrate 100 may be a semiconductor substrate including silicon, germanium, or silicon-germanium. Alternatively, the substrate 100 may be a III-V group compound semiconductor substrate.

According to an exemplary embodiment, the buffer pattern 111b may include protrusions 111ap that protrude in a direction perpendicular to a top surface of the substrate 100. The channel fin patterns 121c may be disposed on top surfaces of the protrusions 111 by of the buffer pattern 111b, respectively.

According to an exemplary embodiment, the buffer pattern 111b may include a material of which a lattice constant is different from that of the substrate 100. In addition, the buffer pattern 111b and the channel fin pattern 121c may include materials that have the same lattice structure but have lattice constants different from each other. For example, each of the buffer pattern 111b and the channel fin pattern 121c may include silicon, germanium, silicon-germanium, or a III-V group compound semiconductor material.

In more detail, if the semiconductor device of the inventive concepts is an NMOS field effect transistor, the buffer pattern 111b may provide a tensile strain to the channel fin patterns 121c. In other words, the buffer pattern 111b may have a lattice constant greater than those of the channel fin patterns 121c. In exemplary embodiments, the buffer pattern 111b may be formed of Si₁₋ₓGeₓ, and the channel fin patterns 121c may be formed of silicon (Si). In other exemplary embodiments, the buffer pattern 111b may be formed of Si₁₋ₓGeₓ, and the channel fin patterns 121c may be formed of Si_{1-y}Ge_{y} (where x>y). In still other exemplary embodiments, the buffer pattern 111b may be formed of In₁₋ₓGaₓAs, and the channel fin patterns 121c may be formed of In_{1-y}Ga_{y}As (where x<y). Alternatively, if the semiconductor device of the inventive concepts is a PMOS field effect transistor, the buffer pattern 111b may provide a compressive strain to the channel fin patterns 121c. In other words, the buffer pattern 111b may have a lattice constant smaller than those of the channel fin patterns 121c. In exemplary embodiments, the buffer pattern 111b may be formed of Si₁₋ₓGeₓ, and the channel fin patterns 121c may be formed of germanium (Ge). In other exemplary embodiments, the buffer pattern 111b may be formed of Si_{1-z}Ge_{z}, and the channel fin patterns 121c may be formed of Si_{1-w}Ge_{w} (where z<w). In still other exemplary embodiments, the buffer pattern 111b may be formed of In_{1-z}Ga_{z}As, and the channel fin patterns 121c may be formed of In_{1-w}Ga_{w}As (where z>w). Thus, the strain of the buffer pattern 111b may be relaxed but the strain may be applied to the channel fin patterns 121c.

Support patterns 125b may be disposed on the buffer pattern 111b. The support patterns 125b may be in contact with both ends of the channel fin patterns 121c. In other words, the support patterns 125b may be in contact with sidewalls of the channel fin pattern 121c opposite to each other in a longitudinal direction (i.e., the first direction D1) of the channel fin pattern 121c. According to an exemplary embodiment, bottom surfaces of the support patterns 125b may be lower than bottom surfaces of the channel fin patterns 121c. According to another exemplary embodiment, the bottom surfaces of the support patterns 125b may be disposed at the substantially height as the bottom surfaces of the channel fin patterns 121c, unlike FIG. 20B. For example, the support patterns 125b may include at least one of an oxide (e.g., silicon oxide), a nitride (e.g., silicon nitride), or an oxynitride (e.g., silicon oxynitride).

The channel fin patterns 121c may extend in the first direction D1 and may be arranged along the first direction D1 and the second direction D2. In addition, the support patterns 125b may be disposed between the channel fin patterns 121c spaced apart from each other in the first direction D1. According to an exemplary embodiment, at least a pair of channel fin patterns 121c among the channel fin patterns 121c may be spaced apart from each other in the second direction D2 and may extend in parallel along the first direction D1. Here, sidewalls adjacent to each other among the sidewalls of the at least the pair of channel fin patterns 121c may be in contact with the same support pattern 125b.

Device isolation patterns 165a may be disposed on the buffer pattern 111b. The device isolation patterns 165a may expose upper portions of the channel fin patterns 121c. In other words, the device isolation patterns 165a may expose upper portions of sidewalls, opposite to each other in the second direction D2, of each of the channel fin patterns 121c. In addition, the device isolation patterns 165a may expose upper portions of the support patterns 125b. In other words, top surfaces of the device isolation patterns 165a may be lower than top surfaces of the support patterns 125b. In exemplary embodiments, the device isolation patterns 165a may include at least one of O₃-tetra ethyl ortho silicate (O₃-TEOS), undoped silicate glass (USG), phosphosilicate glass (PSG), borosilicate glass (BSG), borophosphosilicate glass (BPSG), a high-density plasma (HDP) oxide, undoped silicate glass (USG), fluoride silicate glass (FSG), spin-on-glass (SOG), or Tonen SilaZene (TOSZ). In other exemplary embodiments, the device isolation patterns 165a may include at least one of silicon nitride or silicon oxynitride.

The buffer pattern 111b, the channel fin patterns 121c, the support patterns 125b, and the device isolation patterns 165a may be formed using one of the methods for forming the pattern according to the exemplary embodiments described above.

A gate structure GS may be disposed on the substrate 100 to intersect the channel fin patterns 121c. The gate structure GS may extend in the second direction D2 to intersect the channel fin patterns 121c and may cover the top surfaces and the sidewalls of the channel fin patterns 121c exposed by the device isolation patterns 165a. The gate structure GS may include a gate electrode 185 intersecting the channel fin patterns 121c, gate spacers 181 disposed on both sidewalls of the gate electrode 185, and a gate insulating layer 183 disposed between the gate electrode 185 and the gate spacers 181. The gate insulating layer 183 may also be disposed between the gate electrode 185 and the channel fin patterns 121c and may horizontally extend from the channel fin patterns 121c to partially cover the top surface of each of the device isolation patterns 165a. The gate dielectric layer 183 may extend along a bottom surface of the gate electrode 185.

The gate electrode 185 may include at least one of a conductive metal nitride (e.g., titanium nitride or tantalum nitride) and a metal (e.g., aluminum or tungsten). The gate spacers 181 may include a nitride (e.g., silicon nitride). The gate insulating layer 183 may include at least one high-k dielectric layer. For example, the gate insulating layer 183 may include at least one of, but not limited to, hafnium oxide, hafnium silicate, zirconium oxide, or zirconium silicate.

Even though not shown in the drawings, the gate structure GS may be provided in plurality. The plurality of gate structures GS may be spaced apart from each other in the first direction D1 and may extend in the second direction D2 to intersect the channel fin patterns 121c.

Source/drain regions SD may be disposed on the channel fin patterns 121c at both sides of the gate structure GS. Here, the channel fin patterns 121c disposed between the source/drain regions SD under the gate structure GS may be defined as channel regions CH.

According to an exemplary embodiment, forming the gate structure GS may include forming a dummy gate pattern (not shown) intersecting the channel fin patterns 121c, forming the gate spacers 181 on both sidewalls of the dummy gate pattern, removing the dummy gate pattern to define a gate region exposing the channel fin patterns 121c between the gate spacers 181, and sequentially forming the gate insulating layer 183 and the gate electrode 185 in the gate region. In addition, the source/drain regions SD may be formed in or on the channel fin patterns 121c at both sides of the dummy gate pattern before the formation of the gate electrode 185.

According to another exemplary embodiment, forming the gate structure GS may include sequentially forming the gate insulating layer 183 and a gate conductive layer covering the channel fin patterns 121c, and patterning the gate conductive layer and the gate insulating layer 183. Thereafter, the gate spacers 181 may be formed on both sidewalls of the gate electrode 185. In this case, after the formation of the gate structure GS, the source/drain regions SD may be formed in or on the channel fin patterns 121c at both sides of the gate structure GS.

The semiconductor device described above may include the channel fin patterns 121c of which the degradation of the strain is minimized or prevented. As a result, the semiconductor device may have an improved charge mobility characteristic. This means that electrical characteristics of the semiconductor device are improved.

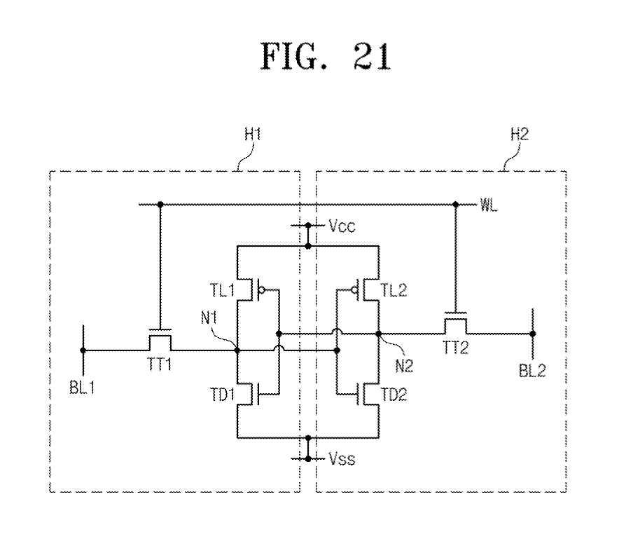

FIG. 21 is an equivalent circuit diagram of a complementary metal-oxide-semiconductor (CMOS) static random access memory (SRAM) cell including a semiconductor device according to exemplary embodiments of the inventive concepts. Referring to FIG. 21, a CMOS SRAM cell may include a pair of driver transistors TD1, TD2, a pair of transfer transistors TT1, TT2, and a pair of load transistors TL1, TL2. The driver transistors TD1, TD2 may be pull-down transistors, the transfer transistors TT1, TT2 may be pass transistors, and the load transistors TL1, TL2 may be pull-up transistors. The driver and transfer transistors TD1, TD2, TT1, TT2 may be NMOS transistors, and the load transistors TL1, TL2 may be PMOS transistors. At least one of the driver, transfer, and load transistors TD1, TD2, TT1, TT2, TL1, TL2 may be one of the field effect transistors according to the aforementioned exemplary embodiments of the inventive concepts.

A first driver transistor TD1 and a first transfer transistor TT1 may be connected in series to each other. A source region of the first driver transistor TD1 may be electrically connected to a ground line Vss, and a drain region of the first transfer transistor TT1 may be electrically connected to a first bit line BL1. A second driver transistor TD2 and a second transfer transistor TT2 may be connected in series to each other. A source region of the second driver transistor TD2 may be electrically connected to the ground line Vss, and a drain region of the second transfer transistor TT2 may be electrically connected to a second bit line BL2.

A source region and a drain region of a first load transistor TL1 may be a power line Vcc and a drain region of the first driver transistor TD1, respectively. A source region and a drain region of a second load transistor TL2 may be the power line Vcc and a drain region of the second driver transistor TD2, respectively. The drain region of the first load transistor TL1, the drain region of the first driver transistor TD1, and a source region of the first transfer transistor TT1 may correspond to a first node N1. The drain region of the second load transistor TL2, the drain region of the second driver transistor TD2, and a source region of the second transfer transistor TT2 may correspond to a second node N2. A gate electrode of the first driver transistor TD1 and a gate electrode of the first load transistor TL1 may be electrically connected to the second node N2, and a gate electrode of the second driver transistor TD2 and a gate electrode of the second load transistor TL2 may be electrically connected to the first node N1. Gate electrodes of the first and second transfer transistors TT1, TT2 may be electrically connected to a word line WL. The first driver transistor TD1, the first transfer transistor TT1, and the first load transistor TL1 may constitute a first half cell H1. The second driver transistor TD2, the second transfer transistor TT2, and the second load transistor TL2 may constitute a second half cell H2.

Exemplary embodiments of the inventive concepts are not limited to the SRAM device. In other exemplary embodiments, the inventive concepts may be applied to a dynamic random access memory (DRAM) device, a magnetic random access memory (MRAM) device, or another semiconductor device and a method of fabricating the same.

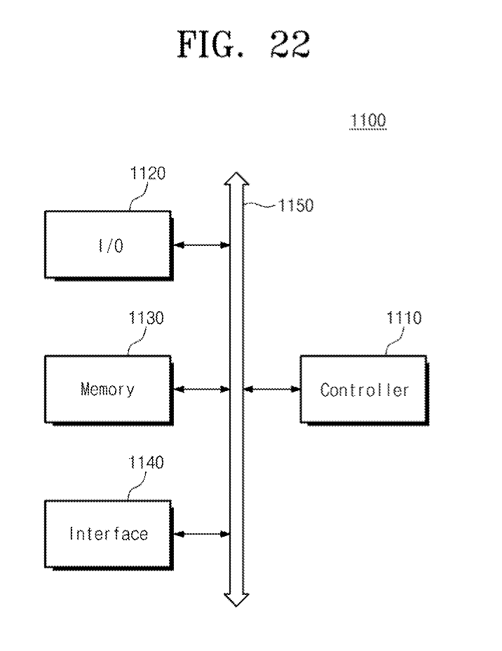

FIG. 22 is a schematic block diagram illustrating an electronic system including a semiconductor device according to exemplary embodiments of the inventive concepts.

Referring to FIG. 22, an electronic system 1100 according to an exemplary embodiment of the inventive concepts may include a controller 1110, an input/output (I/O) unit 1120, a memory device 1130, an interface unit 1140, and a data bus 1150. At least two of the controller 1110, the I/O unit 1120, the memory device 1130, and the interface unit 1140 may communicate with each other through the data bus 1150. The data bus 1150 may correspond to a path through which data are transmitted.

The controller 1110 may include at least one of a microprocessor, a digital signal processor, a microcontroller, or another logic device having a similar function to any one thereof. The I/O unit 1120 may include a keypad, a keyboard and/or a display unit. The memory device 1130 may store data and/or commands. The interface unit 1140 may transmit electrical data to a communication network or may receive electrical data from a communication network. The interface unit 1140 may operate by wireless or cable. For example, the interface unit 1140 may include an antenna or a wireless/cable transceiver. Although not shown in the drawings, the electronic system 1100 may further include a fast DRAM device and/or a fast SRAM device which acts as a cache memory for improving an operation of the controller 1110. The semiconductor device according to the above exemplary embodiments of the inventive concepts may be provided into the memory device 1130, the controller 1110, and/or the I/O unit 1120.

The electronic system 1100 may be applied to a personal digital assistant (PDA), a portable computer, a web tablet, a wireless phone, a mobile phone, a digital music player, a memory card or other electronic products. The other electronic products may receive or transmit information data by wireless.

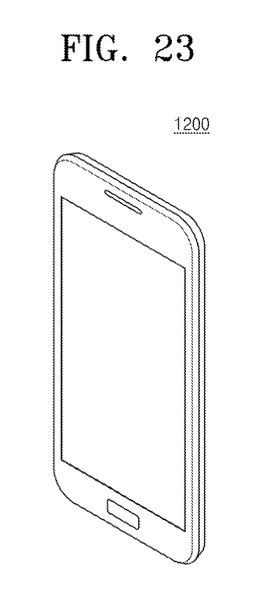

The electronic system 1100 may be applied to electronic control devices of various electronic devices. FIG. 23 illustrates a mobile phone 1200 implemented with the electronic system 1100 of FIG. 22. In other exemplary embodiments, the electronic system 1100 of FIG. 22 may be applied to a portable notebook, a MP3 player, a navigation device, a solid state disk (SSD), a car, or household appliances.

According to an exemplary embodiment of the inventive concepts, the support patterns formed in the channel layer may prevent the degradation of the strain applied to the channel fin patterns while the channel layer is patterned to form the channel fin patterns.

According to another exemplary embodiment of the inventive concepts, the filling insulation patterns may be formed to fill the first trenches defining the preliminary channel fin patterns. Thus, the degradation of the strain applied to the channel fin patterns may be minimized or prevented by the filling insulation patterns being in contact with the channel fin patterns during the formation of the channel fin patterns. In addition, the support patterns are formed to fill the second trenches cutting the preliminary channel fin patterns into the channel fin patterns, so it is possible to prevent the strain applied to the channel fin patterns (i.e., the strain in the longitudinal direction corresponding to the movement direction of charges) from being degraded in subsequent processes.

The semiconductor device formed using the aforementioned exemplary embodiments can have a high charge mobility characteristic, so the electrical characteristics of the semiconductor device can be improved.

While the inventive concepts have been described with reference to exemplary embodiments, it will be apparent to those skilled in the art that various changes and modifications may be made without departing from the spirit and scope of the inventive concepts. Therefore, it should be understood that the above exemplary embodiments are not limiting, but illustrative. Thus, the scope of the inventive concepts are to be determined by the broadest permissible interpretation of the following claims and their equivalents, and shall not be restricted or limited by the foregoing description.

1. A method for forming a pattern of a semiconductor device, the method comprising:
forming a buffer layer on a substrate;
forming a channel layer on the buffer layer;
forming support patterns penetrating the channel layer; and
forming channel fin patterns and a buffer pattern by patterning the channel layer and the buffer layer,
wherein the channel layer includes a material of which a lattice constant is different from that of the buffer layer, and
wherein each of the channel fin patterns has both sidewalls that are in contact with the support patterns and are opposite to each other.

2. The method of claim 1,
wherein forming the support patterns comprises:
forming openings exposing the buffer layer in the channel layer; and
filling the openings with an insulating material, and
wherein the support patterns are formed after forming the channel layer.

3. The method of claim 2, wherein the buffer layer and the channel layer are sequentially formed by an epitaxial growth process using the substrate as a seed layer.

4. The method of claim 1,
wherein forming the support patterns comprises:
forming a support layer on the buffer layer; and
patterning the support layer, and
wherein the support patterns are formed before forming the channel layer.

5. The method of claim 4,
wherein the buffer layer is formed by an epitaxial growth process using the substrate as a seed layer, and
wherein the channel layer is formed by a selective epitaxial growth process using the buffer layer as a seed layer.

6. The method of claim 1,
wherein forming the channel fin patterns comprises:
forming mask patterns on the channel layer; and
etching the channel layer by an etching process using the mask patterns as etch masks to form trenches defining the channel fin patterns, and
wherein each of the mask patterns have both end portions overlapping with the support patterns.

7. The method of claim 6, wherein the mask patterns intersect at least one of the support patterns.

8. The method of claim 6,
wherein an upper portion of the buffer layer is partially etched to form the buffer pattern during the etching process for the formation of the trenches,
wherein the buffer pattern has protrusions defined by the trenches, and
wherein the channel fin patterns are formed on top surfaces of the protrusions.

9. The method of claim 6, further comprises forming device isolation patterns in the trenches,
wherein the device isolation patterns expose upper portions of the channel fin patterns and are formed of a different material from the support patterns.

10. The method of claim 1, wherein the support patterns are formed of a material having an etch selectivity with respect to the channel layer and the buffer layer.

11. The method of claim 1,
wherein the support patterns are arranged to constitute a plurality of rows and a plurality of columns when viewed from a plan view, and
wherein the support patterns of the rows adjacent to each other are arranged in a zigzag form along one direction.

12.-15. (canceled)

16. A method for forming a pattern of a semiconductor device, the method comprising:
sequentially forming a buffer layer and a channel layer on a substrate;
patterning the channel layer and the buffer layer to form first trenches defining preliminary channel fin patterns and a buffer pattern;
forming filling insulation patterns filling the first trenches, the filling insulation patterns covering entire portions sidewalk of the preliminary channel fin patterns; and
forming a plurality of channel fin patterns from each of the preliminary channel fin patterns,
wherein the channel layer includes a material of which a lattice constant is different from that of the buffer layer.

17. The method of claim 16,
wherein forming the plurality of channel fin patterns comprises:
forming mask patterns on the substrate having the filling insulation patterns, the mask patterns partially exposing the preliminary channel fin patterns and the filling insulation patterns; and
performing an etching process using the mask patterns as etch masks,
wherein the channel fin patterns are arranged along a first direction and a second direction intersecting the first direction.

18. The method of claim 17,
wherein the exposed preliminary channel fin patterns and the exposed filling insulation patterns are etched together by the etching process, such that second trenches are formed extending in the second direction, and
wherein each of the preliminary channel fin patterns is cut by the second trenches so as to be divided into the plurality of channel fin patterns.

19. The method of claim 18, further comprising forming support patterns filling the second trenches,
wherein the support patterns are formed of a different material from the filling insulation patterns.

20. The method of claim 17,
wherein the exposed preliminary channel fin patterns among the exposed preliminary channel fin patterns and the exposed filling insulation patterns are selectively etched by the etching process to form a plurality of holes,
wherein each of the preliminary channel fin pattern is cut by the holes so as to be divided into the plurality of channel fin patterns, and
the method further comprising forming support patterns filling the holes.

21. A method for forming a pattern of a semiconductor device, the method comprising:
forming a strain relaxed buffer pattern on a substrate;
forming strained channel fin patterns on the strain relaxed buffer pattern, each of the strained channel fin patterns having sidewalk opposite to each other in a first direction;
forming support patterns disposed on the strain relaxed buffer pattern, the support patterns being in contact with the sidewalls of the strained channel fin patterns;
forming device isolation patterns disposed on the strain relaxed buffer pattern, the device isolation patterns exposing upper portions of the strained channel fin patterns; and
forming a gate electrode extending in a second direction intersecting the first direction to intersect the strained channel fin patterns,
wherein the support patterns include a different material from the device isolation patterns, and
wherein top surfaces of the device isolation patterns are lower than top surfaces of the support patterns.

22. The method of claim 21,
wherein forming the strained channel fin patterns comprises:
forming a buffer layer on a substrate;
forming a channel layer on the buffer layer, the channel layer including a material of which a lattice constant is different from that of the buffer layer;
forming mask patterns on the channel layer; and
etching the channel layer by an etching process using the mask patterns as etch masks to form trenches defining the strained channel fin patterns,
wherein each of the mask patterns has both end portions overlapping with the support patterns.

23. The method of claim 22,
wherein an upper portion of the buffer layer is partially etched to form the strain relaxed buffer pattern during the etching process for the formation of the trenches,
wherein the strain relaxed buffer pattern has protrusions defined by the trenches, and
wherein the strained channel fin patterns are formed on top surfaces of the protrusions.

24. The method of claim 22,
wherein the support patterns are formed after forming the channel layer, or before forming the channel layer, and
wherein the support patterns are formed to penetrate the channel layer.
